(19) United States
(12) Patent Application Publication
(10) Pub. No.: US 2025/0294902 A1
(43) Pub. Date: Sep. 18, 2025

(54) IMAGE SENSOR

(71) Applicant: Samsung Electronics Co., Ltd., Suwon-si (KR)

(72) Inventors: Jae Sang YOO, Suwon-si (KR); Yong Suk Choi, Suwon-si (KR); Ha Kyu Choi, Suwon-si (KR); Sei Young Park, Suwon-si (KR); Seung Jae Lee, Suwon-si (KR)

(73) Assignee: Samsung Electronics Co., Ltd., Suwon-si (KR)

(21) Appl. No.: 19/022,086

(22) Filed: Jan. 15, 2025

(30) Foreign Application Priority Data
Mar. 15, 2024 (KR) 10-2024-0036369

(51) Int. Cl. H10F 39/00

(52) U.S. Cl. CPC H10F 39/8037; H10F 39/811

(57) ABSTRACT

An image sensor includes a substrate including a first surface and a second surface opposing to the first surface, a first pixel including a first floating diffusion region (FD) in the substrate, conductive layers including a first conductive line layer disposed on a shortest distance from the first surface of the substrate in a first direction perpendicular to the first surface among conductive line layers in the conductive layers, a first transistor on the first surface of the substrate, and a wiring connecting the first FD and first transistor and disposed between the first surface of the substrate and the first conductive line layer.

### CROSS-REFERENCE TO RELATED APPLICATION

This application is based on and claims priority from Korean Patent Application No. 10-2024-0036369 filed on Mar. 15, 2024, in the Korean Intellectual Property Office, and all the benefits accruing therefrom under 35 U.S.C. 119, the contents of which in its entirety are herein incorporated by reference.

### BACKGROUND

### 1. Field

The disclosure relates to an image sensor.

### 2. Description of the Related Art

An image sensor is a semiconductor element that converts optical information into an electric signal. Such an image sensor may include a charge coupled device (CCD) image sensor and a complementary metal-oxide semiconductor (CMOS) image sensor.

The image sensor may be configured in the form of a package, and the package may have a structure that protects the image sensor and allows light to enter a photo-receiving surface or a sensing area of the image sensor.

### SUMMARY

Aspects of the disclosure provide an image sensor in which design efficiency of conductive lines connected to transistors of the image sensor is improved and/or enhanced.

Aspects of the disclosure also provide an image sensor in which process margin of the image sensor is improved and/or enhanced.

According to an aspect of the disclosure, there is provided an image sensor including: a substrate comprising a first surface and a second surface opposing to the first surface; a first pixel comprising a first floating diffusion region (FD) in the substrate; conductive layers comprising a first conductive line layer disposed on a shortest distance from the first surface of the substrate in a first direction perpendicular to the first surface among conductive line layers in the conductive layers; a first transistor on the first surface of the substrate; and a wiring connecting the first FD and the first transistor and disposed between the first surface of the substrate and the first conductive line layer, wherein the wiring comprises a first portion extending in a second direction perpendicular to the first direction.

According to another aspect of the disclosure, there is provided an image sensor including: a substrate comprising a first surface and a second surface opposing to the first surface; a first pixel comprising a first floating diffusion region (FD) in the substrate; a second pixel comprising a second FD in the substrate; a third pixel comprising a third FD in the substrate; a fourth pixel comprising a fourth FD in the substrate; conductive layers comprising a first conductive line layer disposed on a shortest distance from the first surface of the substrate in a first direction perpendicular to the first surface among conductive line layers in the conductive layers; a first source follower transistor on the first surface of the substrate; and a wiring connecting first to fourth FDs and the first source follower transistor and disposed between the first surface of the substrate and the first conductive line layer, wherein the wiring comprises a first portion extending in a second direction perpendicular to the first direction.

According to another aspect of the disclosure, there is provided an image sensor including: a substrate comprising a first surface and a second surface opposing to the first surface, first to fourths pixels sharing a first floating diffusion region (FD) in the substrate, conductive layers comprising a first conductive line layer disposed on a shortest distance from the first surface in a first direction perpendicular to the first surface among conductive line layers in the conductive layers, first to second source follower transistors shared by the first to fourth pixels, and a wiring connecting the first FD and the first and second source follower transistors and disposed between the first surface of the substrate and the first conductive line layer, wherein the wiring comprises a first portion extending in a second direction perpendicular to the first direction.

However, aspects of the disclosure are not restricted to the one set forth herein. The above and other aspects of the disclosure will become more apparent to one of ordinary skill in the art to which the disclosure pertains by referencing the detailed description of the disclosure given below.

### BRIEF DESCRIPTION OF DRAWINGS

The above and other aspects and features of the disclosure will become more apparent by describing in detail exemplary embodiments thereof with reference to the attached drawings, in which:

FIG. 1 is an exemplary circuit diagram illustrating a pixel array of an image sensor according to some embodiments;

FIG. 2 is an exemplary layout diagram illustrating the image sensor according to some embodiments;

FIG. 3 is an exemplary cross-sectional view taken along line A-A′ of FIG. 2;

FIG. 4 is an exemplary cross-sectional view taken along line B-B′ of FIG. 2;

FIG. 5 is a layout diagram illustrating the image sensor according to some embodiments;

FIG. 6 is an exemplary cross-sectional view taken along line C-C′ of FIG. 5;

FIG. 7 is an exemplary layout diagram illustrating the image sensor according to some embodiments;

FIG. 8 is an exemplary cross-sectional view taken along line D-D′ of FIG. 7;

FIG. 9 is an exemplary circuit diagram illustrating a pixel array of the image sensor according to some embodiments;

FIG. 10 is an exemplary layout diagram illustrating the image sensor according to some embodiments;

FIG. 11 is an exemplary cross-sectional view taken along line E-E′ of FIG. 10;

FIG. 12 is an exemplary layout diagram illustrating the image sensor of FIG. 9;

FIGS. 13 to 15 are exemplary layout diagrams illustrating the image sensor according to some embodiments;

FIG. 16 is an exemplary cross-sectional view taken along line C-C′ of FIG. 5;

FIG. 17 is an exemplary layout diagram illustrating the image sensor according to some embodiments;

FIG. 18 is an exemplary cross-sectional view taken along line F-F′ of FIG. 18;

FIG. 19 is an exemplary circuit diagram illustrating a pixel array of the image sensor according to some embodiments;

FIG. 20 is an exemplary layout diagram illustrating the image sensor according to some embodiments;

FIG. 21 is an exemplary layout diagram illustrating the image sensor according to some embodiments;

FIG. 22 is an exemplary layout diagram illustrating the pixel array of the image sensor according to some embodiments;

FIGS. 23 and 24 are exemplary layout diagrams illustrating the pixel array of the image sensor according to some embodiments;

FIGS. 25 to 27 are exemplary layout diagrams illustrating the pixel array of

the image sensor according to some embodiments;

FIG. 28 is a diagram showing a conceptual layout of the image sensor according to some embodiments;

FIG. 29 is a diagram showing a conceptual layout of the image sensor according to some embodiments; and

FIGS. 30 to 34 are diagrams illustrating a method of manufacturing an image sensor according to some embodiments.

### DETAILED DESCRIPTION

Hereinafter, the disclosure will be described in detail by explaining embodiments of the disclosure with reference to the accompanying drawings.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component is described as being “connected to,” or “coupled to” another component, it may be directly “connected to,” or “coupled to” the other component, or there may be one or more other components intervening therebetween. In contrast, when an element is described as being “directly connected to,” or “directly coupled to” another element, there can be no other elements intervening therebetween. Likewise, similar expressions, for example, “between” and “immediately between,” and “adjacent to” and “immediately adjacent to,” are also to be construed in the same way. As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, a first component, a first region, a first layer, or a first section referred to in examples described herein may also be referred to as a second member, a second component, a second region, a second layer, or a second section without departing from the teachings of the examples.

The terminology used herein is for describing various examples only and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof. As used herein, an expression “at least one of”' preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment (e.g., as to what an example or embodiment may include or implement) means that at least one example or embodiment exists where such a feature is included or implemented, while all example embodiments are not limited thereto.

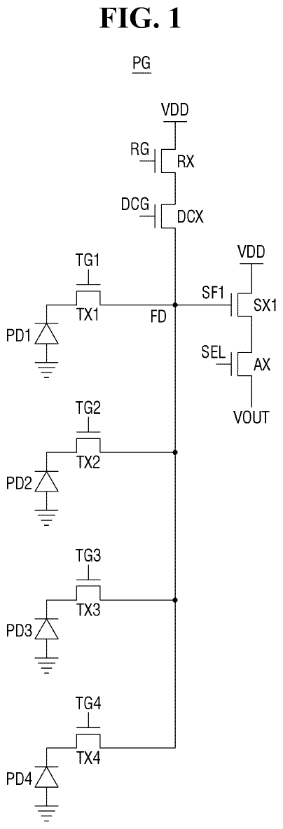

FIG. 1 is an exemplary circuit diagram illustrating a pixel array of an image sensor according to some embodiments.

Referring to FIG. 1, the pixel array of the image sensor according to some embodiments includes a plurality of pixel groups PG.

The pixel group PG may include a first photodiode PD1, a second photodiode PD2, a third photodiode PD3, a fourth photodiode PD4, a first transfer transistor TX1, a second transfer transistor TX2, a third transfer transistor TX3, a fourth transfer transistor TX4, a floating diffusion region FD, a dual conversion gain transistor DCX, a reset transistor RX, a first source follower transistor SX1, and a selection transistor AX. The first to fourth photodiodes PD1, PD2, PD3, and PD4 may share the floating diffusion region FD, the dual conversion gain transistor DCX, the reset transistor RX, the first source follower transistor SX1, and the selection transistor AX. According to another embodiment, the dual conversion gain transistor DCX may be omitted.

Each of the first to fourth photodiodes PD1, PD2, PD3, and PD4 may generate charges based on incident light. For example, each of the first to fourth photodiodes PD1, PD2, PD3, and PD4 may generate charges proportional to an amount of light incident from the outside.

The first transfer transistor TX1 may include a first transfer gate electrode TG1, the second transfer transistor TX2 may include a second transfer gate electrode TG2, the third transfer transistor TX3 may include a third transfer gate electrode TG3, and the fourth transfer transistor TX4 may include a fourth transfer gate electrode TG4. The first gate transfer electrode TG1 is a gate of the first transfer transistor TX1, the second transfer gate electrode TG2 is a gate of the second transfer transistor TX2, the third transfer gate electrode TG3 is a gate of the third transfer transistor TX3, and the fourth transfer gate electrode TG4 is gate of the fourth transfer transistor TX4. Sources of each of the first to fourth transfer transistors TX1, TX2, TX3, and TX4 may be connected to the respective first to fourth photodiodes PD1, PD2, PD3, and PD4, and drains of each of the first to fourth transfer transistors TX1, TX2, TX3, and TX4 may be connected to the floating diffusion region FD. The first to fourth transfer transistors TX1, TX2, TX3, and TX4 may share the floating diffusion region FD as a drain. The charges generated in each of the first to fourth photodiodes PD1, PD2, PD3, and PD4 may be transmitted to the floating diffusion region FD by each of the first to fourth transfer transistors TX1, TX2, TX3, and TX4, and may be accumulated in the floating diffusion region FD. Because the floating diffusion region FD is a region that switches charge to voltage, and has a parasitic capacitance, the charge may be cumulatively stored.

The first source follower transistor SX1 may include a first source follower gate electrode SF1. The first source follower gate electrode SF1 is a gate of the first source follower transistor SX1. For example, the first source follower transistor SX1 may amplify the change in the electrical potential of the floating diffusion region FD that receives charge from the first to fourth photodiodes PD1, PD2, PD3, and PD4, and may output it to an output line VOUT. The first source follower gate electrode SF1 may be connected to the floating diffusion region FD, the drain of the first source follower transistor SX1 may be connected to a power supply voltage VDD, and the source of the first source follower transistor SX1 may be connected to the drain of the selection transistor AX. In an example case in which the first source follower transistor SX1 is turned on, the power supply voltage VDD provided to the drain of the first source follower transistor SX1 may be transferred to the drain of the selection transistor AX.

The selection transistor AX including the selection gate electrode SEL may select pixels to be read out row by row. The selection gate electrode SEL is a gate of the selection transistor AX. In an example case in which the selection transistor AX is turned on, the power supply voltage VDD connected to the drain of the first source follower transistor SX1 may be transferred to the source region of the first source follower transistor SX1.

The dual conversion gain transistor DCX may adjust a conversion gain. A drain of the dual conversion gain transistor DCX may be connected to a source of the reset transistor RX, and a source of the dual conversion gain transistor DCX may be connected to the floating diffusion region FD. The dual conversion gain transistor DCX including the dual conversion gain gate electrode DCG may be, for example, turned on in a high illuminance mode and turned off in a low illuminance mode. The dual conversion gain gate electrode DCG is a gate of the dual conversion gain transistor DCX.

The reset transistor RX may include a reset gate electrode RG. The reset gate electrode RG is a gate of the reset transistor RX. For example, the reset transistor RX may periodically reset the floating diffusion region FD. In an example case in which the reset transistor RX and the dual conversion gain transistor DCX are turned on, the power supply voltage VDD supplied to the drain of the reset transistor RX may be transferred to the floating diffusion region FD.

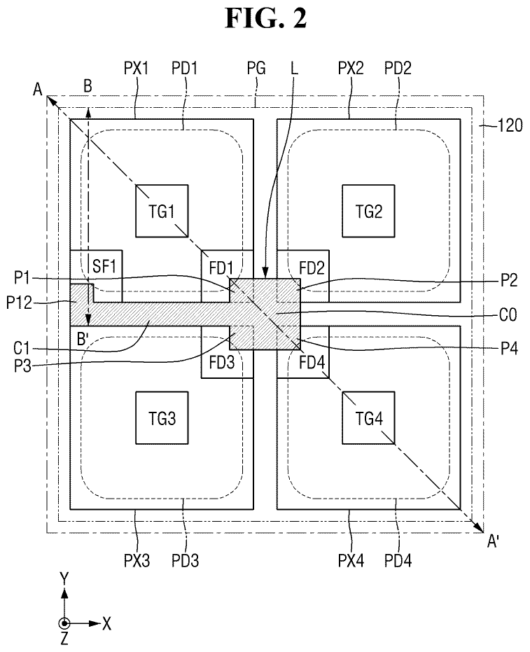

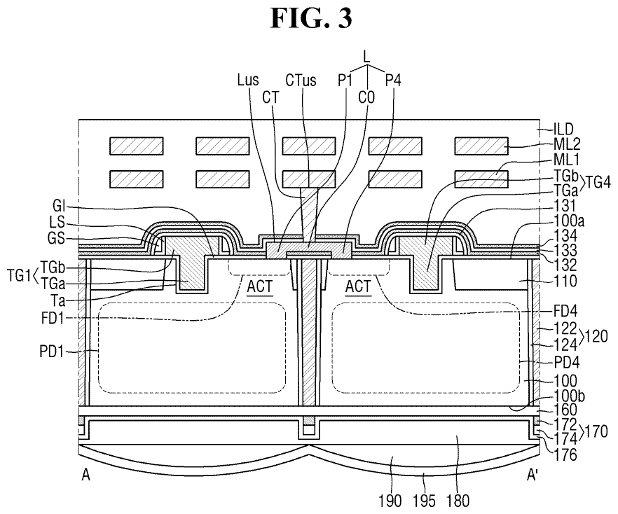

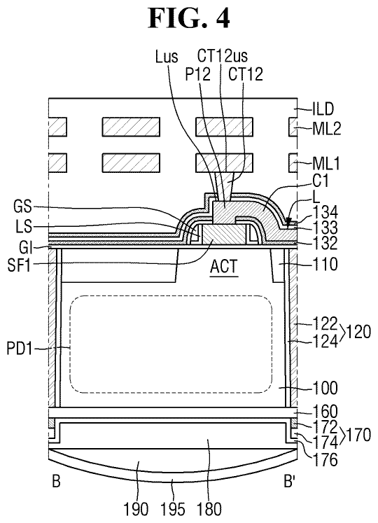

FIG. 2 is an exemplary layout diagram illustrating an image sensor according to some embodiments. FIG. 3 is an exemplary cross-sectional view taken along line A-A′ of FIG. 2. FIG. 4 is an exemplary cross-sectional view taken along line B-B′ of FIG. 2.

Referring to FIGS. 1 to 4, the image sensor according to some embodiments includes a substrate 100, a floating diffusion region FD, a pixel separation pattern 120, first to fourth photodiodes PD1, PD2, PD3, and PD4, first to fourth transfer gate electrodes TG1, TG2, TG3, and TG4, a surface insulating film 160, a grid pattern 170, a first protective film 176, a color filter 180, and a micro lens 190.

The substrate 100 may include a first side 100a and a second side 100b that are opposite to each other. The first side 100a may be referred to as a front side of the substrate 100, and the second side 100b may be referred to as a back side of the substrate 100. However, the disclosure is not limited thereto, and as such, in some cases, the first side 100a may be an upper side of the substrate 100, and the second side 100b may be a lower side of the substrate 100. First and second directions X and Y may intersect each other, and may be parallel to the first side 100a of the substrate 100. A third direction Z may intersect the first and second directions X and Y, and may be perpendicular to the first side 100a of the substrate 100. Hereinafter, the upper side and the lower side are defined with respect to the third direction Z.

In some embodiments, the second side 100b of the substrate 100 may be a photo-receiving surface onto which light is incident. For example, the image sensor according to some embodiments may be a backside illuminated (BSI) image sensor. However, the disclosure is not limited thereto, and as such, according to some other embodiments, the first side 100a may be referred to the back side, and the second side 100b of the substrate 100 may be referred to the front side which is a photo-receiving surface onto which light is incident.

The substrate 100 may be a semiconductor substrate. For example, the substrate 100 may be bulk silicon or silicon-on-insulator (SOI). The substrate 100 may be a silicon substrate. However, the disclosure is not limited thereto, and as such, according to some other embodiments, the substrate 100 may include, but is not limited to, silicon germanium, indium antimonide, lead telluride, indium arsenide, indium phosphide, gallium arsenide or gallium antimonide. In another embodiment, the substrate 100 may have an epitaxial layer is formed on a base substrate.

The pixel group PG may include first to fourth pixels PX1, PX2, PX3, and PX4. The first to fourth pixels PX1, PX2, PX3, and PX4 may be arranged two-dimensionally inside a plane including the first direction X and the second direction Y. For example, the first to fourth pixels PX1, PX2, PX3, and PX4 may be arranged in the form of a matrix. For example, the pixel group PG may include first to fourth pixels PX1, PX2, PX3, and PX4 that are adjacent to each other. The first pixel PX1 and the second pixel PX2 may be adjacent to each other in the first direction X, and the third pixel PX3 and the fourth pixel PX4 may be adjacent to each other in the first direction X. The third pixel PX3 and the first pixel PX1 may be adjacent to each other in the second direction Y, and the fourth pixel PX4 and the second pixel PX2 may be adjacent to each other in the second direction Y. The third pixel PX3 and the second pixel PX2 may be adjacent to each other in a diagonal direction between the first direction X and the second direction Y. The first to fourth pixels PX1, PX2, PX3, and PX4 may be arranged in two rows and two columns.

The plurality of pixel groups PG may be arranged two-dimensionally on the plane including the first direction X and the second direction Y (or the plane intersecting the third direction Z). For example, the plurality of pixel groups PG may be arranged in the form a matrix. Accordingly, a pixel array including a plurality of pixels arranged two-dimensionally (e.g., in the form of a matrix) may be formed.

The pixel separation pattern 120 may be formed in the substrate 100. For example, the pixel separation pattern 120 may be formed inside the substrate 100. The pixel separation pattern 120 may define a plurality of pixels in the substrate 100. For example, the pixel separation pattern 120 may define the first to fourth pixels PX1, PX2, PX3, and PX4 inside the substrate 100. The pixel separation pattern 120 may be provided between the plurality of pixels to separate the plurality of pixels. For example, the pixel separation pattern 120 may surround each of the plurality of pixels (e.g., first to fourth pixels PX1, PX2, PX3, and PX4) from the viewpoint of a plan view. The pixel separation pattern 120 may be referred to as a separation pattern.

For example, the pixel separation pattern 120 may be formed by embedding an insulating material into a deep trench formed by patterning the substrate 100. For example, the pixel separation pattern 120 may extend from the first side 100a toward the second side 100b.

The pixel separation pattern 120 may include a filling pattern 122 and a spacer film 124. The filling pattern 122 may include a conductive material, for example, but not limited to, polysilicon (poly-Si). The spacer film 124 may extend along the side faces of the filling pattern 122. The spacer film 124 may include an insulating material, for example, but not limited to, at least one of silicon oxide, aluminum oxide, tantalum oxide, and combinations thereof. The spacer film 124 may be provided between the filling pattern 122 and the substrate 100. For example, the spacer film 124 may be interposed between the filling pattern 122 and the substrate 100 to electrically separate the filling pattern 122 and the substrate 100.

Each of the first to fourth pixels PX1, PX2, PX3, and PX4 may include respective first to fourth photodiodes PD1, PD2, PD3, and PD4, respective first to fourth transfer transistors TX1, TX2, TX3, and TX4, and respective first to fourth floating diffusion regions FD1, FD2, FD3 and FD4. Because the structures of each of the second to fourth pixels PX2, PX3, and PX4 are the same as the structure of the first pixel PX1, the following description will focus on the first pixel PX1. The floating diffusion region FD of FIG. 1 corresponds to the first to fourth floating diffusion regions FD1, FD2, FD3 and FD4.

The first to fourth floating diffusion regions FD1, FD2, FD3 and FD4 may be formed in the substrate 100. For example, the first to fourth floating diffusion regions FD1, FD2, FD3 and FD4 may be formed inside the substrate 100. The first to fourth floating diffusion regions FD1, FD2, FD3 and FD4 may be adjacent to the first side 100a of the substrate 100. The first to fourth floating diffusion regions FD1, FD2, FD3 and FD4 may be formed in the active region ACT of each of the first to fourth pixels PX1, PX2, PX3, and PX4. For example, each of the first to fourth floating diffusion regions FD1, FD2, FD3 and FD4 may be formed inside the active region ACT of each of the first to fourth pixels PX1, PX2, PX3, and PX4. The first to fourth floating diffusion regions FD1, FD2, FD3 and FD4 may be formed, for example, by ion-implantation of n-type impurities into the p-type substrate 100.

In the image sensor according to some embodiments, the first to fourth floating diffusion regions FD1, FD2, FD3 and FD4 may be provided at a central part of adjacent pixels inside the pixel group PG. The first to fourth floating diffusion regions FD1, FD2, FD3 and FD4 may be connected to each other at the central part of adjacent pixels in the pixel group PG.

In some embodiments, the pixel separation pattern 120 may physically separate the first to fourth floating diffusion regions FD1, FD2, FD3 and FD4. Each of the first to fourth floating diffusion regions FD1, FD2, FD3 and FD4 are separated in the substrate 100 and may connect to each other on the substrate 100 by the wiring.

In some embodiments, the pixel separation pattern 120 does not physically separate the first to fourth floating diffusion regions FD1, FD2, FD3 and FD4 in the substrate 100 and the first to fourth floating diffusion regions FD1, FD2, FD3 and FD4 form a one single large FD. In this case, a portion of the single large FD disposed on the first pixel PX1 is defined as the first floating diffusion region FD1, a portion of the single large FD disposed on the second pixel PX2 is defined as the second floating diffusion region FD2, a portion of the single large FD disposed on the third pixel PX3 is defined as the third floating diffusion region FD3, and a portion of the single large FD disposed on the fourth pixel PX4 is defined as the fourth floating diffusion region FD4. each of the first to fourth pixels PX1, PX2, PX3, and PX4 may share the first to fourth floating diffusion regions FD1, FD2, FD3 and FD4. The pixel separation pattern 120 may not include a region of the pixel group PG. For example, the pixel separation pattern 120 may not include a cut region at the central part of the pixel group PG. For example, the pixel separation pattern 120 may surround each of the first to fourth pixels PX1, PX2, PX3, and PX4.

The first to fourth floating diffusion regions FD1, FD2, FD3 and FD4 may be formed inside the active region ACT of the first to fourth pixels PX1, PX2, PX3, and PX4 that are connected to each other. The first to fourth floating diffusion regions FD1, FD2, FD3 and FD4 provided in the first to fourth pixels PX1, PX2, PX3, and PX4 may be connected to each other at the central part of the first to fourth pixels PX1, PX2, PX3, and PX4 that are adjacent to each other in the pixel group PG. The first to fourth floating diffusion regions FD1, FD2, FD3 and FD4 may be connected to each other in the region in which the pixel separation pattern 120 is cut.

The first photodiode PD1 may be formed in the substrate 100 of the first pixel PX1. For example, the first photodiode PD1 may be formed inside the substrate 100 of the first pixel PX1. For example, the substrate 100 may include a p-type impurity, and the first photodiode PD1 may be formed by ion-implantation of a n-type impurity into the p-type substrate 100. The p-type impurity may include, but is not limited to, boron (B) and the n-type impurity may include, but is not limited to, phosphorus (P) or arsenic (As). Hereinafter, an example in which the substrate 100 includes the p-type impurity will be explained.

The element separation film 110 may be formed in the substrate 100. For example, the element separation film 110 may be formed inside the substrate 100. The element separation film 110 may be formed, for example, by embedding an insulating material into a shallow trench formed by patterning the substrate 100. The element separation film 110 may extend from the first side 100a of the substrate 100, and the lower side of the element separation film 110 may be located inside the substrate 100. The element separation film 110 may define an active region ACT inside the first pixel PX1. The element separation film 110 may include an insulating material, for example, but not limited to, at least one of silicon oxide, silicon nitride, silicon oxynitride, and combinations thereof.

The reset transistor RX, the dual conversion gain transistor DCX, the first source follower transistor SX1, and the selection transistor AX of FIG. 1 may be provided at various positions within the pixel group PG. Hereinafter, an example in which the first source follower transistor SX1 is provided in the first pixel PX1 will be explained.

The first transfer transistor TX1 may be formed on the first side 100a of the substrate 100. Referring to FIG. 3, the first transfer gate electrode TG1 of the first transfer transistor TX1 may be formed on the active region ACT of the first pixel PX1. The first transfer gate electrode TG1 may be adjacent to the first photodiode PD1. The placement of the first transfer transistor TX1 inside the first pixel PX1 is merely an example, and is not limited thereto.

In the image sensor according to some embodiments, the first transfer gate electrode TG1 may be a vertical transfer gate. For example, at least a part of the first transfer gate electrode TG1 may be provided inside the substrate 100. For example, a trench Ta extending from the first side 100a of the substrate 100 may be formed inside the substrate 100. The first transfer gate electrode TG1 may include a first extending part TGa that fills the first trench Ta, and a second extending part TGb that extends along the first side 100a of the substrate 100 on the first extending part TGa.

The first source follower transistor SX1 may be formed on the first side 100a of the substrate 100. Referring to FIG. 4, the first source follower gate electrode SF1 of the first source follower transistor SX1 may be formed on the first side 100a of the substrate 100. The first source follower gate electrode SF1 may be formed in an active region ACT different from the active region ACT in which the first floating diffusion region FD1 is formed. The placement of the first source follower transistor SX1 inside the pixel group PG is merely an example and is not limited thereto. Hereinafter, an example in which the first source follower transistor SX1 is provided in the first pixel PX1 will be explained.

A gate insulating layer GI may be interposed between the first transfer gate electrode TG1 and the substrate 100. The gate insulating layer GI may be interposed between the first source follower gate electrode SF1 and the substrate 100. The first transfer gate electrode TG1 and the first source follower gate electrode SF1 may be provided on the gate insulating layer GI. The gate insulating layer GI may further extend along the first side 100a of the substrate 100. The gate insulating layer GI may extend (e.g., conformally) along the profile of the first side 100a of the substrate 100. For example, the gate insulating layer GI may extend conformally along the profile of the first side 100a of the substrate 100. The gate insulating layer GI may include, for example, but not limited to, silicon oxide or metal oxide.

A gate spacer GS may be formed on the gate insulating layer GI. The gate spacer GS may be formed on the side wall of the first transfer gate electrode TG1. For example, the gate spacer GS may be formed on the side wall of the second extending part TGb of the first transfer gate electrode TG1. The gate spacer GS may be formed on the side wall of the first source follower gate electrode SF1. A liner spacer LS may be formed between the second extending part TGb of the first transfer gate electrode TG1 and the gate spacer GS, and between the gate insulating layer GI and the gate spacer GS. The liner spacer LS may be formed between the first source follower gate electrode SF1 and the gate spacer GS, and between the gate insulating layer GI and the gate spacer GS.

For example, the gate spacer GS may include silicon nitride, and the liner spacer LS may include silicon oxide. However, the disclosure is not limited thereto, and as such, the gate spacer GS and the liner spacer LS may be made of another material.

A first insulating layer 131 may be provided on the first transfer gate electrode TG1 and the gate spacer GS. The first insulating layer 131 may extend along the first transfer gate electrode TG1 and the gate spacer GS. The first insulating layer 131 may extend (e.g., conformally) along the profile of the first transfer gate electrode TG1 and the profile of the gate spacer GS. The first insulating layer 131 may expose the gate insulating layer GI that does not overlap the first transfer gate electrode TG1 and the gate spacer GS in the third direction Z. The first insulating layer 131 may extend along the first source follower gate electrode SF1 and the gate spacer GS. The first insulating layer 131 may extend (e.g., conformally) along the profile of the first source follower gate electrode SF1 and the profile of the gate spacer GS. The first insulating layer 131 may expose the gate insulating layer GI that does not overlap the first source follower gate electrode SF1 and the gate spacer GS in the third direction Z.

A second insulating layer 132 may be provided on the first insulating layer 131 and the gate insulating layer GI. A second insulating layer 132 may extend along the first insulating layer 131 and the gate insulating layer GI. The second insulating layer 132 may extend (e.g., conformally) along the profile of the first insulating layer 131 and the profile of the gate insulating layer GI exposed by the first insulating layer 131. According to an embodiment, elements connected to the same node in the pixel array (or elements having the same potential) may be connected through a wiring of a lower level, which is lower than the first conductive line ML1. For example, the wiring of the lower level, which connects the elements having the same potential, may be lower than the lowest level among the conductive lines ML1 and ML2 formed on the first side 100a of the substrate 100.

In the image sensor according to some embodiments, the first source follower gate electrode SF1 and the first to fourth floating diffusion regions FD1, FD2, FD3 and FD4 may be connected to each other through the wiring of the lower level, which is lower than the first conductive line ML1. The number and placement of gate electrodes connected to the first to fourth floating diffusion regions FD1, FD2, FD3 and FD4 are merely exemplary and are not limited thereto. Hereinafter, an example in which the first source follower gate electrode SF1 connected to the first to fourth floating diffusion regions FD1, FD2, FD3 and FD4 is provided in the first pixel PX1 will be explained.

For example, the wiring of the lower level may be a wiring L, which connects the first to fourth floating diffusion regions FD1, FD2, FD3 and FD4 of the first to fourth pixels PX1, PX2, PX3, and PX4 to the first source follower gate electrode SF1. The wiring L may include, but is not limited to, polysilicon.

The wiring L may include first first penetrating parts P1, P2, P3, and P4, a second first penetrating part P12, and first connecting parts C0 and C1. According to some embodiment, the penetrating parts may be referred to as protruding parts are extending parts.

Each of the first first penetrating parts P1, P2, P3, and P4 may extend into the gate insulating layer GI and the second insulating layer 132. Each of the first first penetrating parts P1, P2, P3, and P4 may extend, for example, in the third direction Z. Each of the first first penetrating parts P1, P2, P3, and P4 penetrates through the gate insulating layer GI and the second insulating layer 132, and may be connected to each of the first to fourth floating diffusion regions FD1, FD2, FD3 and FD4 of each of the first to fourth pixels PX1, PX2, PX3, and PX4. Each of the first first penetrating parts P1, P2, P3, and P4 may be in contact with the each of first to fourth floating diffusion regions FD1, FD2, FD3 and FD4 of the respective first to fourth pixels PX1, PX2, PX3, and PX4.

A second first penetrating part P12 may extend into the first insulating layer 131 and the second insulating layer 132. The second first penetrating part P12 may extend, for example, in the third direction Z. The second first penetrating part P12 penetrates the first insulating layer 131 and the second insulating layer 132, and may be connected to the first source follower gate electrode SF1. The second first penetrating part P12 may be in contact with the first source follower gate electrode SF1.

The first connecting parts C0 and C1 may extend along the second insulating layer 132. The first connecting parts C0 and C1 may extend along the profile (e.g., conformally) of the second insulating layer 132. A first first connecting part C0 extends along the second insulating layer 132, and may connect the first first penetrating parts P1, P2, P3, and P4. A second first connecting part C1 extends along the second insulating layer 132, and may connect the second first penetrating part P12 and the first first connecting part C0. The first connecting parts C0 and C1 may be insulated from the substrate 100 by the second insulating layer 132, the first insulating layer 131 or the gate insulating layer GI. The placement of the second first connecting part C1 within the pixel group PG is merely an example, and is not limited thereto.

In the image sensor according to some embodiments, each of the elements (or portions) connected to the same node (e.g., elements or portions having the same potential) is connected to respective penetrating parts extending in the third direction Z, and the connecting part extends along the pixel separation pattern 120 from the viewpoint of a plan view (e.g., from the viewpoint of a plan view including the first direction X and the second direction Y), and may connect the respective penetrating parts to each other. The respective penetrating parts may penetrate the first insulating layer 131 and the second insulating layer 132 or the gate insulating layer GI and the second insulating layer 132, and may be connected to each of the portions connected to the same node, and the connecting part may extend along the pixel separation pattern 120 from the viewpoint of the plan view. The gate insulating layer GI and the second insulating layer 132 may be interposed between the connecting part and the pixel separation pattern 120. Hereinafter, the plan view is defined as a plan view that includes the first direction X and the second direction Y. For example, from the viewpoint of a plan view, the first connecting part C1 may extend along the pixel separation pattern 120. At least a part of the first connecting part C1 may overlap the pixel separation pattern 120 in the third direction Z.

A third insulating layer 133 may be provided on the second insulating layer 132 and the wiring L. The third insulating layer 133 may extend along the second insulating layer 132 and the wiring L. The third insulating layer 133 may extend (e.g., conformally) along the profile of the second insulating layer 132 and the profile of the wiring L exposed by the second insulating layer 132. A fourth insulating layer 134 may be provided on the third insulating layer 133. The fourth insulating layer 134 may extend along the third insulating layer 133. The fourth insulating layer 134 may extend along the profile (e.g., conformally) of the third insulating layer 133.

For example, the first insulating layer 131 and the third insulating layer 133 may include silicon oxide, and the second insulating layer 132 and the fourth insulating layer 134 may include silicon nitride. However, the disclosure is not limited thereto, and as such, according to another embodiment, the first insulating layer 131 and the third insulating layer 133 may be made of another material, and the second insulating layer 132 and the fourth insulating layer 134 may be made of another material.

An interlayer insulating film ILD may be formed on the first side 100a of the substrate 100. The interlayer insulating film ILD may be provided on the fourth insulating layer 134. For example, the interlayer insulating film ILD may cover the fourth insulating layer 134. The interlayer insulating film ILD may have, for example, a single film or multi film structure of at least one of silicon oxide, silicon nitride, silicon oxynitride, and porous insulator.

A plurality of conductive lines ML1 and ML2 may be formed in the interlayer insulating film ILD. For example, the plurality of conductive lines ML1 and ML2 may be formed inside the interlayer insulating film ILD. The plurality of conductive lines ML1 and ML2 may be electrically connected to the active region ACT and the gate electrode. For example, a first conductive line ML1 and a second conductive line ML2 may be formed on the first side 100a of the substrate 100 inside the interlayer insulating film ILD along the third direction Z. The second conductive line ML2 may be provided at an upper level than the first conductive line ML1. The first conductive line ML1 may be provided at the lowest level among the plurality of conductive lines ML1 and ML2. The first conductive line ML1 may be closest to the first side 100a of the substrate 100 among the plurality of conductive lines ML1 and ML2. The placement and number of the conductive lines ML1 and ML2 inside the interlayer insulating film ILD are only examples, and the disclosure is not limited thereto. As such, according to another embodiment, a conductive line may be provided at an upper level. For example, a conductive line may be provided at a level higher than a level of the second conductive line ML2.

The first contacts CT and CT12 may be provided inside the interlayer insulating film ILD. The first contacts CT and CT12 may connect the first conductive line ML1 and the wiring L. The placement and number of first contacts CT and CT12 are merely exemplary and are not limited thereto. At least one conductive line may further be formed on the second conductive line ML2.

The wiring L may be connected to the first conductive line ML1 through the first contacts CT and CT12. The first contacts CT and CT12 penetrate the interlayer insulating film ILD, the fourth insulating layer 134, and the third insulating layer 133, and may be connected to the wiring L. The first contacts CT and CT12 may be in contact with the wiring L. For example, a first first contact CT may be connected to the first first connecting part C0, and a second first contact CT12 may be connected to the second first penetrating part P12.

The wiring L is formed at a lower level than the first conductive line ML1 and the first contacts CT and CT12. An upper side Lus of the wiring L is provided below upper sides CTus and CT12us of the first contacts CT and CT12. The wiring L connects the first to fourth floating diffusion regions FD1, FD2, FD3 and FD4 and the first source follower gate electrode SF1 at a level different from the level of the first conductive line ML1 and the first contacts CT and CT12. Therefore, the design efficiency of the first conductive line ML1 may be improved and/or enhanced.

Further, since the second first connecting part C1 of the wiring L is formed along the pixel separation pattern 120 from the viewpoint of a plan view, the degree of freedom in disposing various elements on the pixel may be improved and/or enhanced.

Furthermore, since the first contacts CT and CT12 are formed on the wiring L containing polysilicon, the resistance may be improved and/or enhanced and the process margin of the first contact CT and CT12 may be improved and/or enhanced, compared to a case where the first contacts CT and CT12 are formed in the impurity region such as the floating diffusion region FD.

The surface insulating film 160 may be formed on the second side 100b of the substrate 100. The surface insulating film 160 may conformally extend along the second side 100b of the substrate 100. The surface insulating film 160 may include an insulating material, for example, but not limited to, at least one of silicon oxide, silicon nitride, silicon oxynitride, aluminum oxide, hafnium oxide, and combinations thereof.

The color filter 180 may be provided on the surface insulating film 160. The color filter 180 may be arranged to correspond to each unit pixel (e.g., the first pixel PX1). For example, the plurality of color filters 180 may be arranged two-dimensionally (e.g., in the form of a matrix) in a plane including the first direction X and the second direction Y. The color filter 180 may have various colors depending on the pixels (e.g., the first pixel PX1). For example, the color filter 180 may include a red color filter, a green color filter, a blue color filter, a yellow filter, a magenta filter, and a cyan filter, and may further include a white filter.

A grid pattern 170 may be formed on the surface insulating film 160. The grid pattern 170 is formed in a grid pattern from the viewpoint of the plan view, and may be interposed between the color filters 180. The grid pattern 170 may include a metal pattern 172 and a low refractive index pattern 174. For example, the metal pattern 172 and the low refractive index pattern 174 may be sequentially stacked on the surface insulating film 160.

The metal pattern 172 may include, for example, but not limited to, at least one of titanium (Ti), titanium nitride (TiN), tantalum (Ta), tantalum nitride (TaN), tungsten (W), aluminum (Al), copper (Cu), and a combination thereof.

The low refractive index pattern 174 may include a low refractive index material that has a lower refractive index than silicon (Si). For example, the low refractive index pattern 174 may include, but not limited to, at least one of silicon oxide, aluminum oxide, tantalum oxide, and combinations thereof.

A first protective film 176 may be provided on the surface insulating film 160 and the grid pattern 170. For example, the first protective film 176 may conformally extend along the profiles of the surface insulating film 160 and the grid pattern 170. The first protective film 176 may include, for example, but not limited to, aluminum oxide.

A micro lens 190 may be formed on the color filter 180. The micro lens 190 may be arranged to correspond to each pixel (e.g., the first pixel PX1). For example, the plurality of micro lenses 190 may be arranged two-dimensionally (e.g., in the form of a matrix) inside a plane including the first direction X and the second direction Y.

The micro lens 190 has a convex shape, and may have a predetermined radius of curvature. Accordingly, the micro lens 190 may collect the light that is incident on the photodiode (e.g., the first photodiode PD). The micro lens 190 may include, for example, but not limited to, a light-transmitting resin.

A second protective film 195 may be formed on the micro lens 190. The second protective film 195 may extend along the surface of the micro lens 190. The second protective film 195 may include, for example, an inorganic oxide film. For example, the second protective film 195 may include, but not limited to, at least one of silicon oxide, titanium oxide, zirconium oxide, hafnium oxide, and combinations thereof. For example, the second protective film 195 may include low temperature oxide (LTO).

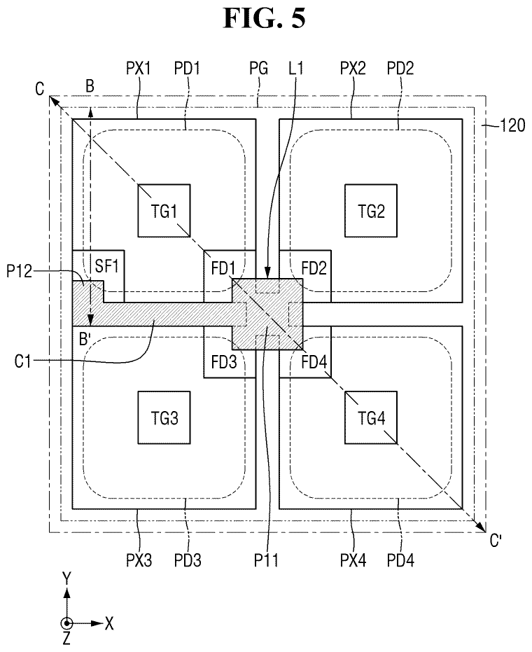

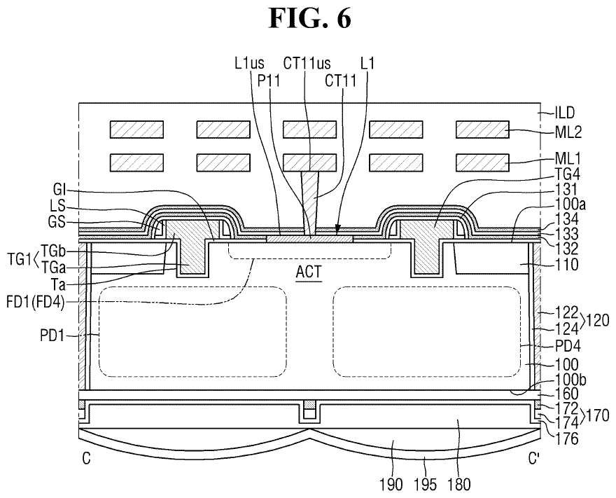

FIG. 5 is a layout diagram illustrating an image sensor according to some embodiments. FIG. 6 is an exemplary cross-sectional view taken along line C-C′ of FIG. 5. For convenience of explanation, the explanation will focus on the points that are different from those explained using FIGS. 1 to 4.

For reference, FIG. 4 is an exemplary cross-sectional view taken along line B-B′ of FIG. 5. For example, the illustration in FIG. 4 may correspond to line B-B′ of FIG. 2 and FIG. 5, and as such, overlapping description may be omitted. A wiring L and an upper side Lus of the wiring L of FIG. 4 correspond to a first wiring L1 and an upper side Llus of the first wiring L1 of FIGS. 5 and 6, respectively.

Referring to FIGS. 4 to 6, in the image sensor according to some

embodiments, the pixel separation pattern 120 may include a cut region at the central part of adjacent pixels in the pixel group PG. The pixel separation pattern 120 may not be provided at the central part of adjacent pixels in the pixel group PG.

For example, the pixel separation pattern 120 may include the cut region at the central part of the first to fourth pixels PX1, PX2, PX3, and PX4 adjacent to each other in the pixel group PG. The pixel separation pattern 120 may be cut between the first pixel PX1 and the fourth pixel PX4 and/or between the second pixel PX2 and the third pixel PX3. The pixel separation pattern 120 extending between the first pixel PX1 and the second pixel PX2, the pixel separation pattern 120 extending between the first pixel PX1 and the third pixel PX3, the pixel separation pattern 120 extending between the second pixel PX2 and the fourth pixel PX4, and the pixel separation pattern 120 extending between the third pixel PX3 and the fourth pixel PX4 may not be connected to each other at the central part of the pixel group PG.

The first wiring L1 connects the first to fourth floating diffusion regions FD1, FD2, FD3 and FD4 and the first source follower gate electrode SF1. The first wiring L1 may include, but is not limited to, polysilicon. The first wiring L1 may include a first first penetrating part P11, a first connecting part C1, and a second first penetrating part P12.

The first first penetrating part P11 may extend into the gate insulating layer GI and the second insulating layer 132. The first first penetrating part P11 may extend, for example, in the third direction Z. The first first penetrating part P11 penetrates through the gate insulating layer GI and the second insulating layer 132, and may be connected to the floating diffusion region FD. The first first penetrating part P11 may be in contact with the floating diffusion region FD.

The first connecting part C1 extends along the second insulating layer 132, and may connect the first first penetrating part P11 and the second first penetrating part P12.

A first contact CT11 may be provided inside the interlayer insulating film ILD. The first contact CT11 may connect the first conductive line ML1 and the first wiring L1. The placement and number of first contacts CT11 are merely exemplary, and are not limited thereto. At least one conductive line may further be formed on the second conductive line ML2.

The first wiring L1 may be connected to the first conductive line ML1 through first contacts CT11 and CT12. The first contacts CT11 and CT12 penetrate the interlayer insulating film ILD, the fourth insulating layer 134, and the third insulating layer 133, and may be connected to the first wiring L1. The first contacts CT11 and CT12 may be in contact with the first wiring L1. For example, the first contact CT11 may be connected to the first first penetrating part P11. The first contact CT12 may be connected to the second first penetrating part P12.

The first wiring L1 is formed at a lower level than the first conductive line ML1 and the first contacts CT11 and CT12. The upper side Llus of the first wiring L1 is provided below the upper sides CT1lus and CT12us of the first contacts CT11 and CT12.

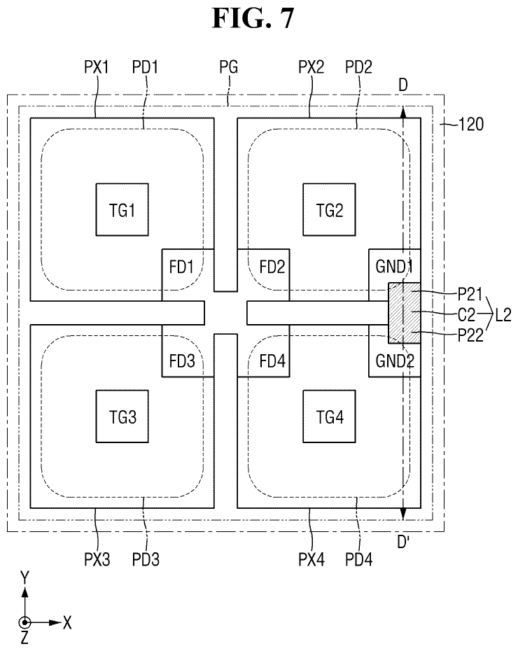

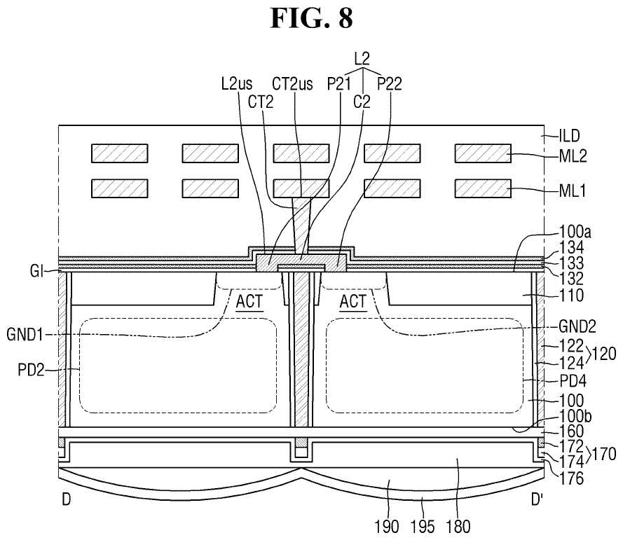

FIG. 7 is a layout diagram illustrating an image sensor according to some embodiments. FIG. 8 is an exemplary cross-sectional view taken along line D-D′ of FIG. 7. For convenience of explanation, points different from those explained using FIGS. 1 to 6 will be mainly explained.

In the image sensor according to some embodiments, ground regions GND1 and GND2 may be connected to each other through the wiring of the lower level lower than the first conductive line ML1. The number and placement of the ground regions GND1 and GND2 connected to each other are merely exemplary and are not limited thereto. Hereinafter, an example in which the first and second ground regions GND1 and GND2 connected to each other are provided in each of the second pixel PX2 and the fourth pixel PX4 will be explained.

Each of the first and second ground regions GND1 and GND2 may be formed in the first side 100a of the substrate 100. For example, each of the first and second ground regions GND1 and GND2 may be formed inside the first side 100a of the substrate 100. Each of the first and second ground regions GND1 and GND2 may be formed in each of the active region ACT of the second pixel PX2 and the active region ACT of the fourth pixel PX4. Each of the first and second ground regions GND1 and GND2 may be formed by ion-implantation of a highly concentrated p-type impurity into the substrate 100. Each of the first and second ground region GND1 and GND2 may be the ground region of FIG. 1.

In the image sensor according to some embodiments, a second wiring L2 connects the first ground region GND1 and the second ground region GND2. The second wiring L2 may include, but is not limited to, polysilicon.

The second wiring L2 may include a first second penetrating part P21, a second connecting part C2, and a second second penetrating part P22.

The first second penetrating part P21 and the second second penetrating part P22 may extend into the first insulating layer 131 and the second insulating layer 132. The first second penetrating part P21 and the second second penetrating part P22 may extend, for example, in the third direction Z. Each of the first second penetrating part P21 and the second second penetrating part P22 penetrates through the first insulating layer 131 and the second insulating layer 132, and may be connected to each of the first ground region GND1 and the second ground region GND2. Each of the first second penetrating part P21 and the second second penetrating part P22 may be in contact with each of the first ground region GND1 and the second ground region GND2.

The second connecting part C2 may extend along the second insulating layer 132. The second connecting part C2 may extend along the profile (e.g., conformally) of the second insulating layer 132. The second connecting part C2 extends along the second insulating layer 132, and may connect the first second penetrating part P21 and the second second penetrating part P22. The second connecting part C2 may be insulated from the substrate 100 by the second insulating layer 132 and the gate insulating layer GI.

For example, from the viewpoint of a plan view, the second connecting part C2 may extend along the pixel separation pattern 120. At least a part of the second connecting part C2 may overlap the pixel separation pattern 120 in the third direction Z. The placement of the second connecting part C2 inside the pixel group PG is merely exemplary and not limited thereto.

The second wiring L2 may be connected to the first conductive line ML1 through the second contact CT2. The second contact CT2 may connect the first conductive line ML1 and the second wiring L2. The second contact CT2 penetrates the interlayer insulating film ILD, the fourth insulating layer 134, and the third insulating layer 133, and may be connected to the second wiring L2. The second contact CT2 may be in contact with the second wiring L2.

The second wiring L2 is formed at a lower level than the first conductive line ML1 and the second contact CT2. An upper side L2us of the second wiring L2 is provided below an upper side CT2us of the second contact CT2. The second wiring L2 connects the first ground region GND1 and the second ground region GND2 at a level different from the levels of the first conductive line ML1 and the second contact CT2.

The image sensor according to some embodiments may further include the first source follower gate electrode SF1 and the first wiring L1 of FIGS. 5 and 6.

In addition, element or portions connected to the same node in the pixel array (elements or portions having the same potential) may be connected through the wiring of the lower level, which is lower than the first conductive line ML1. Referring to FIG. 1, in an example case in which the source of the reset transistor RX and the drain of the dual conversion gain transistor DCX are provided in different active regions ACT, the source of the reset transistor RX and the drain of the dual conversion gain transistor DCX may be connected through the second wiring L2. In this case, the second wiring L2 may include first second penetrating part P21 and second second penetrating part P22 which penetrate the first insulating layer 131 and the second insulating layer 132, and are connected to the source of each reset transistor RX and the drain of the dual conversion gain transistor DCX, and a second connecting part C2 that connects the first second penetrating part P21 and the second second penetrating part P22. In another example case in which the source of the first source follower transistor SX1 and the drain of the selection transistor AX are provided in different active regions ACT, the source of the first source follower transistor SX1 and the drain of the selection transistor AX may be connected through the second wiring L2.

In the image sensor according to some embodiments, a pixel group PG of FIG. 7 may correspond to the pixel group PG of FIG. 2. For example, the pixel separation pattern 120 in FIG. 7 may not include the cut region between the first to fourth pixels PX1, PX2, PX3, and PX4. The image sensor according to some embodiments may further include the first source follower gate electrode SF1 and the wiring L of FIGS. 2 to 4.

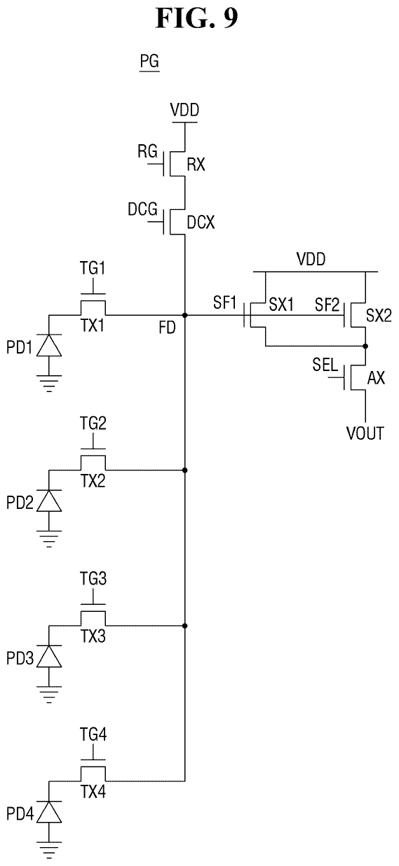

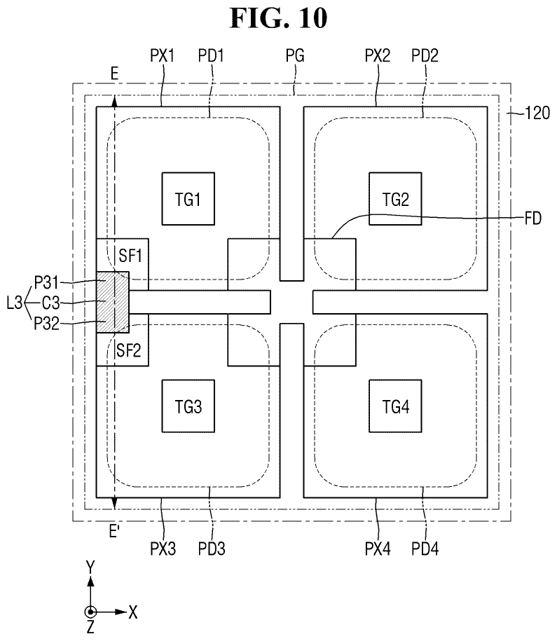

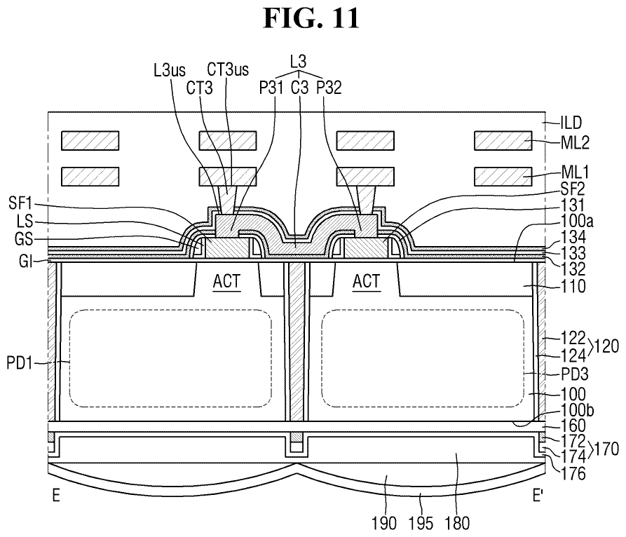

FIG. 9 is an exemplary circuit diagram illustrating a pixel array of an image sensor according to some embodiments. FIG. 10 is an exemplary layout diagram illustrating an image sensor according to some embodiments. FIG. 11 is an exemplary cross-sectional view taken along line E-E′ of FIG. 10. For convenience of explanation, points that are different from those explained using FIGS. 1 and 8 will be mainly explained.

Referring to FIGS. 9 to 11, the pixel group PG according to some embodiments may include a plurality of source follower transistors SX1 and SX2. The placement of each source follower transistor SX1 and SX2 inside the pixel group PG is merely an example and is not limited thereto. Hereinafter, an example in which the pixel group PG includes a first source follower transistor SX1 provided on the first pixel PX1 and a second source follower transistor SX2 provided on the third pixel PX3 will be explained.

The first source follower transistor SX1 and the second source follower transistor SX2 may be connected in parallel. Because the operation of the second source follower transistor SX2 is the same as the operation of the first source follower transistor SX1, repeated explanation will not be provided.

The second source follower transistor SX2 may include a second source follower gate electrode SF2. The second source follower gate electrode SF2 is a gate of the second source follower transistor SX2. The second source follower gate electrode SF2 may be formed in the active region ACT of the third pixel PX3. The placement of the second source follower gate electrode SF2 inside the third pixels PX3 is merely an example, and is not limited thereto.

The gate insulating layer GI may be interposed between the second source follower gate electrode SF2 and the substrate 100. The second source follower gate electrode SF2 may be provided on the gate insulating layer GI.

The gate spacer GS may be formed on the side wall of the second source follower gate electrode SF2. The liner spacer LS may be formed between the second source follower gate electrode SF2 and the gate spacer GS, and between the gate insulating layer GI and the gate spacer GS.

The first insulating layer 131 may be provided on the second source follower gate electrode SF2 and the gate spacer GS. For example, the first insulating layer 131 may extend along the second source follower gate electrode SF2 and the gate spacer GS. The first insulating layer 131 may extend (e.g., conformally) along the profile of the second source follower gate electrode SF2 and the profile of the gate spacer GS. The first insulating layer 131 may expose the gate insulating layer GI that does not overlap the second source follower gate electrode SF2 and the gate spacer GS in the third direction Z.

In the image sensor according to some embodiments, the gate electrode may be connected to each other through the wiring of the lower level, which is lower than the first conductive line ML1. The number and placement of gate electrodes connected to each other are merely exemplary and are not limited thereto. Hereinafter, an example in which the pixel group PG includes a first source follower gate electrode SF1 provided in the first pixel PX1 and a second source follower gate electrode SF2 provided in the third pixel PX3 will be explained.

A third wiring L3 connects the first source follower gate electrode SF1 and the second source follower gate electrode SF2. The third wiring L3 may include, but is not limited to, polysilicon.

The third wiring L3 may include a first third penetrating part P31, a third connecting part C3, and a second third penetrating part P32. Because the first third penetrating part P31 corresponds to the second first penetrating part P12 of FIGS. 2 and 6, repeated explanation will not be provided.

The second third penetrating part P32 may extend into the first insulating layer 131 and the second insulating layer 132. The second third penetrating part P32 may extend, for example, in the third direction Z. The second third penetrating part P32 penetrates the first insulating layer 131 and the second insulating layer 132, and may be connected to the second source follower gate electrode SF2. The second third penetrating part P32 penetrates the first insulating layer 131 and the second insulating layer 132, and may be connected to the second source follower gate electrode SF2.

The third connecting part C3 may extend along the second insulating layer 132. The third connecting part C3 may extend along the profile (e.g., conformally) of the second insulating layer 132. The third connecting part C3 extends along the second insulating layer 132, and may connect the first third penetrating part P31 and the second third penetrating part P32. The third connecting part C3 may be insulated from the substrate 100 by the second insulating layer 132 and the gate insulating layer GI. For example, from the viewpoint of a plan view, the third connecting part C3 may extend along the pixel separation pattern 120. At least a part of the third connecting part C3 may overlap the pixel separation pattern 120 in the third direction Z. The placement of the third connecting part C3 inside the pixel group PG is merely an example, and is not limited thereto.

The third wiring L3 may be connected to the first conductive line ML1 through the third contact CT3. The third contact CT3 may connect the first conductive line ML1 and the third wiring L3. The third contact CT3 penetrates the interlayer insulating film ILD, the fourth insulating layer 134, and the third insulating layer 133, and may be connected to the third wiring L3. The third contact CT3 may be in contact with the third wiring L3.

The third wiring L3 is formed at a lower level than the first conductive line ML1 and the third contact CT3. An upper side L3us of the third wiring L3 is provided below an upper side CT3us of the third contact CT3. The third wiring L3 connects the first source follower gate electrode SF1 and the second source follower gate electrode SF2 at a level different from the level of the first conductive line ML1 and the third contact CT3.

In the image sensor according to some embodiments, the pixel group PG may further include a second wiring L2 of FIG. 7.

In addition, gate electrodes having the same potential (gate electrodes connected to the same node) inside the pixel group PG may be connected through the third wiring L3. For example, referring to FIG. 1, the pixel group PG may further include a transistor having a gate electrode that is driven by the same signal as the first transfer gate electrode TG1 of the first transfer transistor TX1. The gate electrode of the transistor may be connected to the first transfer gate electrode TG1 by the third wiring L3. In this case, the third wiring L3 may include each of the first third penetrating part P31 and the second third penetrating part P32 which penetrate the first insulating layer 131 and the second insulating layer 132, and are connected to the gate electrode of each transistor and the first transfer gate electrode TG1, and a third connecting part C3 which connects the first third penetrating part P31 and the second third penetrating part P32.

In the image sensor according to some embodiments, the pixel group PG of FIG. 10 may correspond to the pixel group PG of FIG. 2. For example, in FIG. 10, the pixel separation pattern 120 may not include a cut region between the first to fourth pixels PX1, PX2, PX3, and PX4.

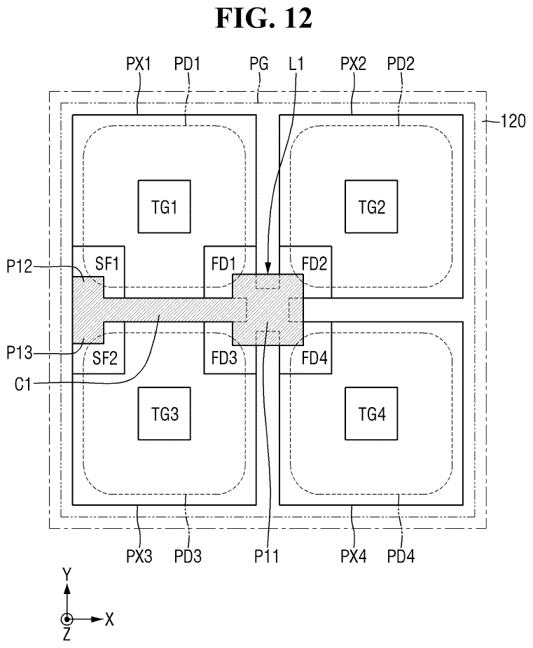

FIG. 12 is an exemplary layout diagram illustrating the image sensor of FIG. 9. For convenience of explanation, points different from those explained using FIGS. 1 to 11 will be mainly explained.

Referring to FIG. 12, in the image sensor according to some embodiments, the first to fourth floating diffusion regions FD1, FD2, FD3 and FD4 and the gate electrode may be connected to each other through wiring of the lower level, which is lower than the first conductive line (ML1 of FIG. 5). The number and placement of gate electrodes connected to the first to fourth floating diffusion regions FD1, FD2, FD3 and FD4 are merely exemplary and are not limited thereto. Hereinafter, an example in which the first source follower transistor SX1 is provided in the first pixel PX1 and the second source follower transistor SX2 is provided in the third pixel PX3 will be explained.

The first wiring L1 connects the first to fourth floating diffusion regions FD1, FD2, FD3 and FD4, the first source follower gate electrode SF1, and the second source follower gate electrode SF2.

The first wiring L1 may further include a third first penetrating part P13. Because the third first penetrating part P13 corresponds to the second third penetrating part P32 of FIGS. 10 and 11, repeated explanation will not be provided.

The first connecting part C1 may extend along the second insulating layer 132, and connect the first first penetrating part P11, the second first penetrating part P12, and the third first penetrating part P13.

The image sensor according to some embodiments may further include the first and second ground regions GND1 and GND2 and the second wiring L2 of FIGS. 7 and 8.

In the image sensor according to some embodiments, a pixel group PG of FIG. 12 may correspond to the pixel group PG of FIG. 2. For example, in FIG. 12, the pixel separation pattern 120 may not include a cut region between the first to fourth pixels PX1, PX2, PX3, and PX4.

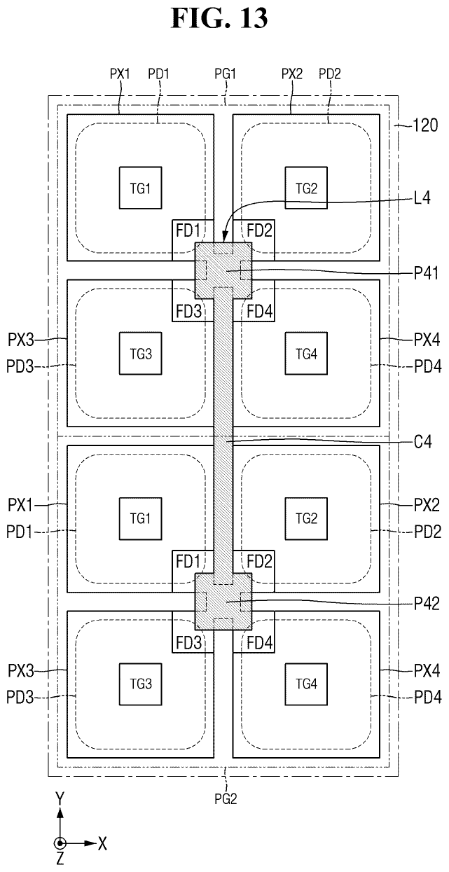

FIGS. 13 to 15 are exemplary layout diagrams illustrating an image sensor according to some embodiments. For convenience of explanation, points that are different from those explained using FIGS. 1 to 10 will be mainly explained.

Referring to FIGS. 13 to 15, each of the first pixel group PG1 and the second pixel group PG2 may correspond to the pixel group PG explained using FIGS. 1 to 12.

Referring to FIG. 13, in the image sensor according to some embodiments, some of the plurality of pixel groups may be connected to each other in the floating diffusion region. The number and placement of pixel groups whose floating diffusion regions are connected to each other are merely exemplary and not limited thereto. Hereinafter, an example in which the pixel group includes a first pixel group PG1 and a second pixel group PG2 whose first to fourth floating diffusion regions FD1, FD2, FD3 and FD4 are connected to each other will be explained.

A fourth wiring L4 connects the first to fourth floating diffusion regions FD1, FD2, FD3 and FD4 of the first pixel group PG1 and the first to fourth floating diffusion regions FD1, FD2, FD3 and FD4 of the second pixel group PG2. The fourth wiring L4 may include, but is not limited to, polysilicon.

The fourth wiring L4 may include a first fourth penetrating part P41, a second fourth penetrating part P42, and a fourth connecting part C4.

The first fourth penetrating part P41 may be connected to the first to fourth floating diffusion regions FD1, FD2, FD3 and FD4 of the first pixel group PG1. The second fourth penetrating part P42 may be connected to the first to fourth floating diffusion regions FD1, FD2, FD3 and FD4 of the second pixel group PG2. Because each of the first fourth penetrating part P41 and the second fourth penetrating part P42 corresponds to the first first penetrating part P11 of FIGS. 5 and 6, repeated explanation will not be provided.

The fourth connecting part C4 may connect the first fourth penetrating part P41 and the second fourth penetrating part P42. The fourth connecting part C4 corresponds to the first connecting part C1 in FIGS. 5 and 6, and therefore, repeated explanation will not be provided.

For example, the first pixel group PG1 and the second pixel group PG2 may be adjacent to each other. For example, the second pixel group PG2 and the first pixel group PG1 may be adjacent to each other in the second direction Y. Unlike this example, the first pixel group PG1 and the second pixel group PG2 may be adjacent to each other in the first direction X.

In the image sensor according to some embodiments, at least a part of the fourth connecting part C4 may overlap the pixel separation pattern 120 in the third direction Z. From the viewpoint of a plan view, at least a part of the fourth connecting part C4 may extend along the pixel separation pattern 120. For example, from the viewpoint of a plan view, the fourth connecting part C4 may extend along the pixel separation pattern 120 between the third pixel PX3 and the fourth pixel PX4 of the first pixel group PG1, and the pixel separation pattern 120 between the first pixel PX1 and the second pixel PX2 of the second pixel group PG2.

In the image sensor according to some embodiments, a pixel group PG of FIG. 13 may correspond to the pixel group PG of FIG. 2. For example, in FIG. 13, the pixel separation pattern 120 may not include a cut region between the first to fourth pixels PX1, PX2, PX3, and PX4.

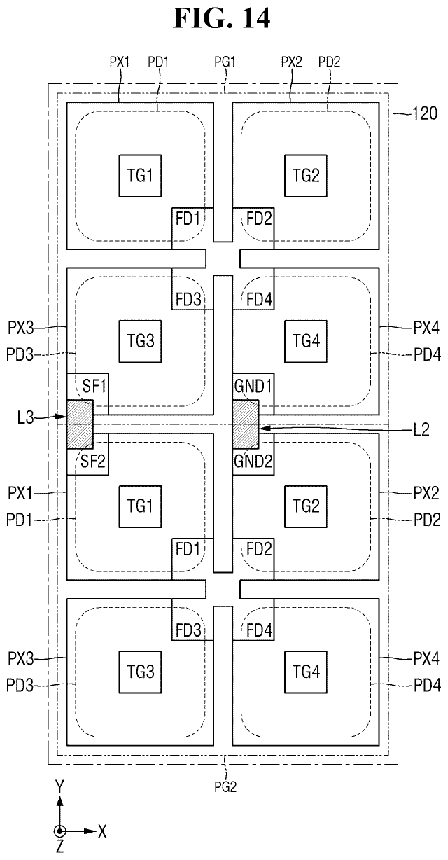

Referring to FIG. 14, in the image sensor according to some embodiments, some of the plurality of pixel groups may have gate electrodes connected to each other. The number and placement of pixel groups having the gate electrodes connected to each other are merely exemplary and are not limited thereto. Hereinafter, an example in which the pixel group includes a first pixel group PG1 including the first source follower gate electrode SF1 and a second pixel group PG2 including the second source follower gate electrode SF2, and the first source follower gate electrode SF1 and the source follower gate electrode SF2 are connected to each other will be explained.

The first source follower gate electrode SF1 may be provided on the third pixel PX3 of the first pixel group PG1. The second source follower gate electrode SF2 may be provided on the first pixel PX1 of the second pixel group PG2. The third wiring L3 connects the first source follower gate electrode SF1 and the second source follower gate electrode SF2.

In the image sensor according to some embodiments, some of the plurality of pixel groups may have ground regions connected to each other. The number and placement of pixel groups having the ground regions connected to each other are merely exemplary and are not limited thereto. Hereinafter, an example in which the pixel group includes a first pixel group PG1 and a second pixel group PG2 that share a first ground region GND1 and a second ground region GND2 will be explained.

The first ground region GND1 may be provided on the fourth pixel PX4 of the first pixel group PG1. The second ground region GND2 may be provided on the second pixel PX2 of the second pixel group PG2. The second wiring L2 connects the first ground region GND1 and the second ground region GND2.

In the image sensor according to some embodiments, the first and second pixel groups PG1 and PG2 may include only one of the third wiring L3 and the second wiring L2. In the image sensor according to some embodiments, the first and second pixel groups PG1 and PG2 may further include the fourth wiring L4 of FIG. 13. At this time, the second wiring L2 may be provided to be separated from and insulated from the fourth wiring L4.

In the image sensor according to some embodiments, each of the first and second pixel group PG1 and PG2 of FIG. 14 may correspond to the pixel group PG of FIG. 2. For example, in FIG. 14, the pixel separation pattern 120 may not include a cut region between the first to fourth pixels PX1, PX2, PX3, and PX4.

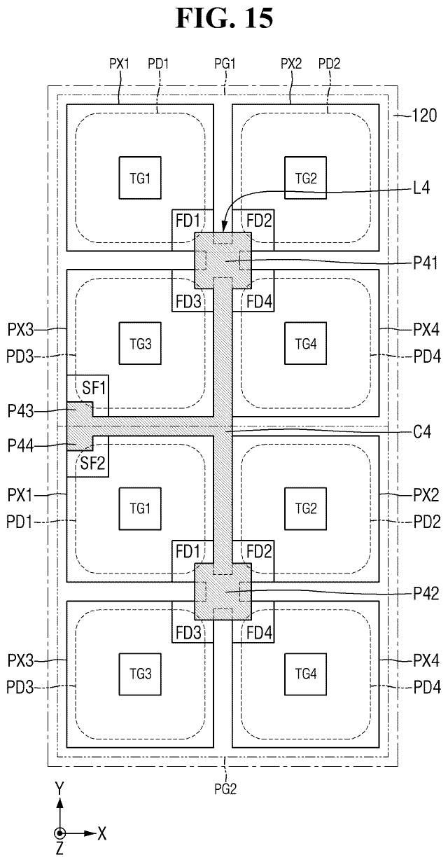

Referring to FIG. 15, in the image sensor according to some embodiments, in some of the plurality of pixel groups, the floating diffusion region and the gate electrode may be connected to each other. The number and placement of pixel groups having the floating diffusion regions and the gate electrodes connected to each other are merely exemplary and are not limited thereto. Hereinafter, an example in which the pixel group includes a first pixel group PG1 including the first source follower gate electrode SF1 and a second pixel group PG2 including the second source follower gate electrode SF2, the first source follower gate electrode SF1 and the second source follower gate electrode SF2 are connected to each other, and the first to fourth floating diffusion regions FD1, FD2, FD3 and FD4 of the first and second pixel groups PG1 and PG2 are connected to each other will be explained.

The fourth wiring L4 may further include a third fourth penetrating part P43 and a fourth fourth penetrating part P44. Because each of the third fourth penetrating part P43 and the fourth fourth penetrating part P44 correspond to each of the first third penetrating part P31 and the second third penetrating part P32 of FIGS. 10 and 11, repeated explanation will not be provided. The fourth connecting part C4 connects the fourth penetrating parts P41, P42, P43, and P44.

In the image sensor according to some embodiments, the first and second pixel groups PG1 and PG2 may further include the first and second ground regions GND1 and GND2 and the second wiring L2 of FIG. 14. At this time, the second wiring L2 may be provided to be spaced from and insulated from the fourth wiring L4.

In the image sensor according to some embodiments, each of the first and second pixel groups PG1 and PG2 of FIG. 15 may correspond to the pixel group PG of FIG. 2. For example, in FIG. 15, the pixel separation pattern 120 may not include a cut region between the first to fourth pixels PX1, PX2, PX3, and PX4.

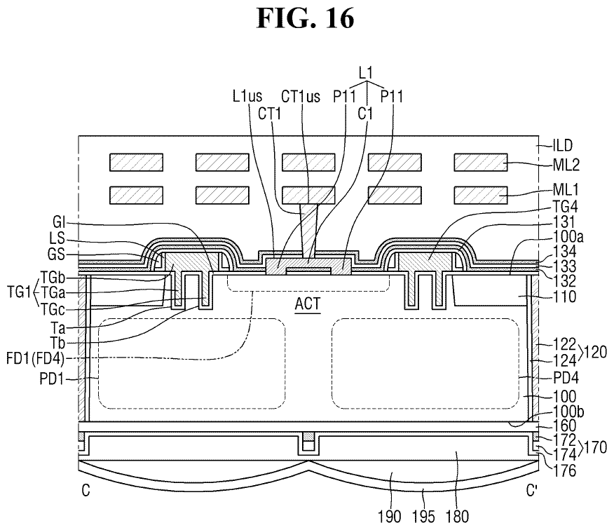

FIG. 16 is an exemplary cross-sectional view taken along line C-C′ of FIG. 5. For convenience of explanation, points different from those explained using FIGS. 1 to 6 will be mainly explained.

Referring to FIG. 16, in the image sensor according to some embodiments, the first transfer gate electrode TG1 may further include a third extending part TGc. For example, first and second trenches Ta and Tb extending from the first side 100a of the substrate 100 and spaced apart from each other may be formed inside the substrate 100. The first transfer gate electrode TG1 may include a first extending part TGa that fills the first trench Ta, a third extending part TGc that fills the second trench Tb, and a second extending part TGb that extends along the first side 100a of the substrate 100 and connects the first extending part TGa and the third extending part TGc.

In the image sensor according to some embodiments, there may be a plurality of first first penetrating parts P11. Each of the first first penetrating parts P11 may be in contact with the floating diffusion region FD, and may be connected to each other by the first connecting part C1.

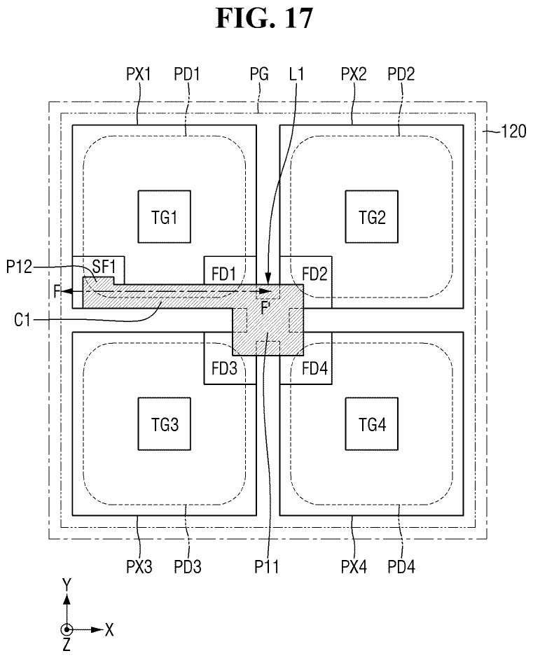

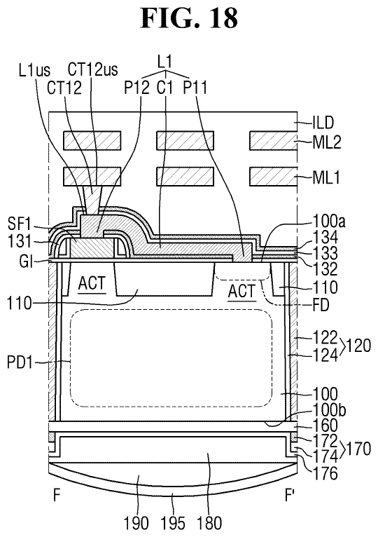

FIG. 17 is an exemplary layout diagram illustrating an image sensor according to some embodiments. FIG. 18 is an exemplary cross-sectional view taken along line F-F′ of FIG. 17. For convenience of explanation, points different from those explained using FIGS. 1 to 6 will be mainly explained.

Referring to FIGS. 17 and 18, in the image sensor according to some embodiments, at least a part of the first connecting part C1 may overlap the element separation film 110 in the third direction Z. The first connecting part C1 may connect the first first penetrating part P11 and the second first penetrating part P12 on the element isolation film 110.

In the image sensor according to some embodiments, the pixel group PG of FIG. 17 may correspond to the pixel group PG of FIG. 2. For example, in FIG. 17, the pixel separation pattern 120 may not include a cut region between the first to fourth pixels PX1, PX2, PX3, and PX4.

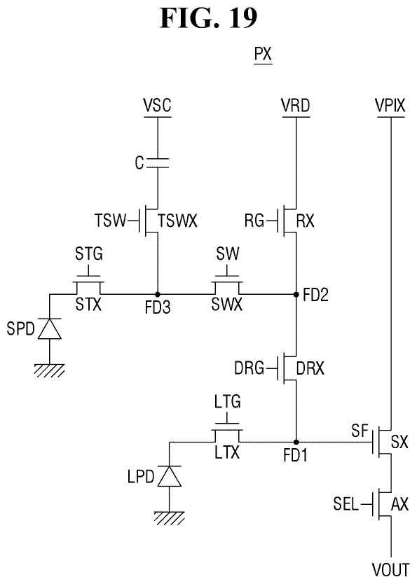

FIG. 19 is an exemplary circuit diagram illustrating a pixel array of an image sensor according to some embodiments.

Referring to FIG. 19, a pixel array according to some embodiments includes a plurality of pixels PX.

For example, the pixel PX may include a large photodiode LPD, a small photodiode SPD, a first floating diffusion region FD1, a second floating diffusion region FD2, a third floating diffusion region FD3, a first transfer transistor LTX, a second transfer transistors STX, a source follower transistor SX, a selection transistor AX, a connecting transistor DRX, a reset transistor RX, a first switch transistor SWX, a capacitor C, and a second switch transistor TSWX.

The large photodiode LPD may generate charge in proportion to the amount of light incident from the outside. The large photodiode LPD may convert light incident on the first pixel LPX1 into charges. One end of the large photodiode LPD may be connected to the ground voltage.

The first transfer transistor LTX may be connected between the large photodiode LPD and the first floating diffusion region FD1. One end of the first transfer transistor LTX may be connected to the large photodiode LPD, and the other end of the first transfer transistor LTX may be connected to the first floating diffusion region FD1. The first transfer transistor LTX may be driven by a first transfer signal applied through the first transfer gate electrode LTG of the first transfer transistor LTX. The first transfer transistor LTX may transfer the charge generated by the large photodiode LPD to the first floating diffusion region FD1.

A source follower gate electrode SF of the source follower transistor SX may be connected to the first floating diffusion region FD1. The source follower gate electrode SF is connected to the first floating diffusion region FD1 and may be applied with charge. The source follower transistor SX may amplify a change in the electric potential of the first floating diffusion region FD1 and output it as an output voltage VOUT. In an example case in which the source follower transistor SX is turned on, the source follower transistor SX may transfer a first voltage VPIX to the selection transistor AX.

The selection transistor AX may be connected to the source follower transistor SX and the output voltage VOUT. The selection transistor AX may select a pixel region to be read out row by row. The selection transistor AX may be driven by a row selection signal applied to the selection gate electrode SEL of the selection transistor AX.

The connecting transistor DRX may connect the first floating diffusion region FD1 and the second floating diffusion region FD2. The connecting transistor DRX may be driven by a connection signal applied to the connecting gate electrode DRG of the connecting transistor DRX.

The reset transistor RX may be driven by a reset signal that is applied to the reset gate electrode RG of the reset transistor RX. In an example case in which the reset transistor RX is turned on, the reset transistor RX may transfer a second voltage VRD to the second floating diffusion region FD2. Accordingly, the first pixel LPX1 and the second pixel SPX1 may be reset.

The first switch transistor SWX may be located between the second floating diffusion region FD2 and the third floating diffusion region FD3. The first switch transistor SWX may be driven by a first switch signal that is applied to the first switch gate electrode SW of the first switch transistor SWX. In an example case in which the first switch transistor SWX is turned on, the first switch transistor SWX may connect the second floating diffusion region FD2 and the third floating diffusion region FD3.

The capacitor C and the second switch transistor TSWX may be located between a third voltage VSC and the third floating diffusion region FD3. The second switch transistor TSWX may be driven by a second switch signal that is applied to the second switch gate electrode TSW of the second switch transistor TSWX. In an example case in which the second switch transistor TSWX is turned on, the second switch transistor TSWX may connect the third floating diffusion region FD3 and the capacitor C. The second switch transistor TSWX may transfer charge overflowing from the small photodiode SPD to the capacitor C. The capacitor C may store charge overflowing from the small photodiode SPD. For example, the capacitor C may not be provided in the first region REG1 and the second region REG2.

At least some of the first to third voltages VPIX, VRD, and VSC may be identical to each other. In another embodiment, the first to third voltages VPIX, VRD, and VSC may be different from each other.

The small photodiode SPD may generate charges in proportion to the amount of light incident from the outside. The small photodiode SPD may convert light incident on the second pixel SPX1 into charge. One end of the small photodiode SPD may be connected to the ground voltage.

The second transfer transistor STX may be connected between the small photodiode SPD and the second floating diffusion region FD2. One end of the second transfer transistor STX may be connected to the small photodiode SPD, and the other end of the second transfer transistor STX may be connected to the third floating diffusion region FD3. The second transfer transistor STX may include a second transfer gate electrode STG. The second transfer transistor STX may be driven by a second transfer signal, and the second transfer signal may be applied through the second transfer gate electrode STG. The second transfer transistor STX may transmit the charge generated by the small photodiode SPD to the third floating diffusion region FD3. The first floating diffusion region FD1 and the third floating diffusion region FD3 may be connected by the first switch transistor SWX and the connecting transistor DRX.

FIG. 20 is an exemplary layout diagram illustrating an image sensor according to some embodiments. For convenience of explanation, the explanation will focus on the points that are different from those explained using FIGS. 1 to 19.

Referring to FIGS. 19 and 20, in the image sensor according to some embodiments, a pixel PX may include a first region REG1 and a second region REG2. The large photodiode LPD may be formed in the first region REG1, and the small photodiode SPD may be formed in the second region REG2. From the viewpoint of a plan view, the area of the first region REGI may be larger than the area of the second region REG2. From the viewpoint of a plan view, the total area of large photodiode LPD may be larger than the total area of small photodiode SPD. The large photodiode LPD may have a relatively large photo-receiving area compared to the small photodiode SPD.

In the image sensor according to some embodiments, from the viewpoint of a plan view, the first region REG1 may have an octagonal shape, and the second region REG2 may have a square shape. One second region REG2 may be surrounded by four first regions REG1. Four second regions REG2 may be provided to be adjacent to four sides among the eight sides of the first region REG1. However, the disclosure is not limited thereto, and as such, the shapes of the first region REG1 and the second region REG2 may vary.

In the image sensor according to some embodiments, first impurity regions 101a and 101b of the first region REG1 and a second impurity region 102 of the second region REG2 of the pixel PX may be connected to each other through wiring of the lower level, which is lower than the first conductive line (ML1 of FIG. 3). The number and placement of the first impurity regions 101a and 101b connected to each other and the number and placement of the second impurity regions 102 are merely exemplary and are not limited thereto. Hereinafter, an example in which the first region REGI of the pixel PX includes the first impurity regions 101a and 101b, and the second region REG2 includes the second impurity region 102 will be explained.

A sixth wiring L6 may connect the second impurity region 102 of the second region REG2 and the first impurity regions 101a and 101b of the first region REG1. The sixth wiring L6 may include, but is not limited to, polysilicon.

In the image sensor according to some embodiments, the first region REG1 may include a plurality of first impurity regions 101a and 101b. The plurality of first impurity regions 101a and 101b may be connected to each other through a wiring of the lower level, which is lower than the first conductive line (ML1 of FIG. 3). The sixth wiring L6 may connect the plurality of first impurity regions 101a and 101b.

The sixth wiring L6 may include a first sixth penetrating part P61, a second sixth penetrating part P62, and a third sixth penetrating part P63 and a sixth connecting part C6. The first sixth penetrating part P61 is connected to a first first impurity region 101a, the second sixth penetrating part P62 is connected to a second first impurity region 101b, and the third sixth penetrating part P63 may be connected to the second impurity region 102. The sixth connecting part C6 may connect the first sixth penetrating part P61, the second sixth penetrating part P62, and the third sixth penetrating part P63.

Because the first first impurity region 101a, the second first impurity region 101b, the first sixth penetrating part P61, the second sixth penetrating part P62, and the sixth connecting part C6 that connects the first sixth penetrating part P61 and the second sixth penetrating part P62 correspond to each of the first ground region GND1, the second ground region GND2, the first second penetrating part P21, the second second penetrating part P22, and the second connecting part C2 of FIGS. 5 and 6, repeated explanations will not be provided. The first first impurity region 101a, the second impurity region 102, the first sixth penetrating part P61, the third sixth penetrating part P63, and the sixth connecting parts C6 that connects the first sixth penetrating part P61 and the third sixth penetrating part P63 correspond to each of the first ground region GND1, the second ground region GND2, the first second penetrating part P21, the second second penetrating part P22, and the second connecting part C2 of FIGS. 5 and 6, repeated explanations will not be provided. For example, the first impurity regions 101a and 101b and the second impurity region 102 are formed in the substrate 100, the first sixth penetrating part P61, the second sixth penetrating part P62, and the third sixth penetrating part P63 may penetrate the gate insulating layer GI and the second insulating layer 132, and the sixth connecting part C6 may extend along the second insulating layer 132. However, the first impurity regions 101a and 101b and the second impurity region 102 may be various impurity regions other than the ground region. For example, the first impurity regions 101a and 101b and the second impurity region 102 may be the third floating diffusion region FD3 of FIG. 19.

In the image sensor according to some embodiments, the sixth connecting part C6 may extend along the pixel separation pattern 120 from the viewpoint of a plan view.

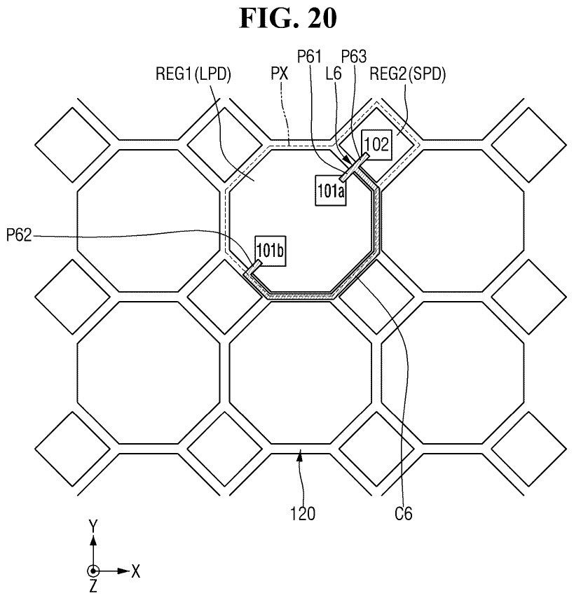

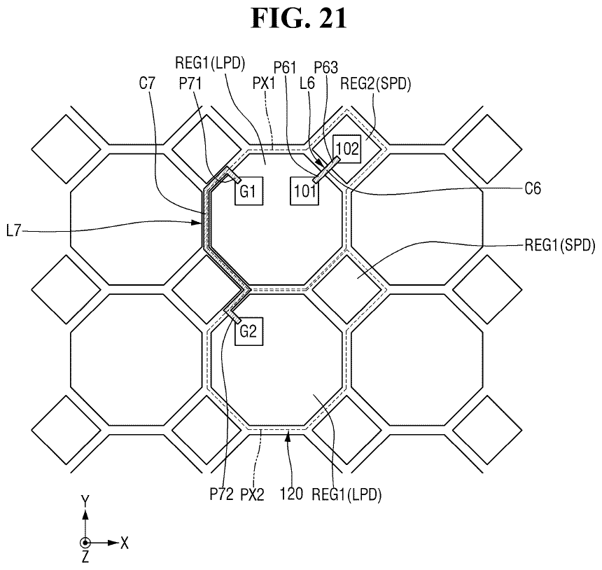

FIG. 21 is an exemplary layout diagram illustrating an image sensor according to some embodiments. For convenience of explanation, points different from those explained using FIGS. 1 to 20 will be mainly explained.

Referring to FIG. 21, each of the first pixel PX1 and the second pixel PX2 may correspond to the pixel PX explained using FIGS. 19 to 20.

In the image sensor according to some embodiments, gate electrodes of different pixels may be connected to each other through wiring of the lower level, which is lower than the first conductive line (ML1 of FIG. 3). The number and placement of pixels whose gate electrodes are connected to each other are merely exemplary and are not limited thereto. Hereinafter, an example in which the gate electrode G of the first pixel PX1 and the gate electrode G of the second pixel PX2 are connected to each other will be explained.

A seventh wiring L7 may connect the first gate electrode G1 of the first pixel PX1 and the second gate electrode G2 of the second pixel PX2. The seventh wiring L7 may include, but is not limited to, polysilicon. For example, the first and second gate electrodes G1 and G2 may be provided in the first region REGI of each of the first and second pixels PX1 and PX2. The placement of the first gate electrode G1 in the first pixel PX1 and the placement of the second gate electrode G2 in the second pixel PX2 are merely exemplary and are not limited thereto.

The seventh wiring L7 may include a first seventh penetrating part P71 and a second seventh penetrating part P72, and a seventh connecting part C7. The first seventh penetrating part P71 is connected to the first gate electrode G1 of the first pixel PX1, the second seventh penetrating part P72 is connected to the second gate electrode G2 of the second pixel PX2, and the seventh connecting part C7 may connect the first seventh penetrating part P71 and the second seventh penetrating part P72. Because the first gate electrode G1, the second gate electrode G2, the first seventh penetrating part P71, the second seventh penetrating part P72, and the seventh connecting part C7 correspond to each of the first source follower gate electrode SF1, the second source follower gate electrode SF2, the first third penetrating part P31, the second third penetrating part P32, and the third connecting part C3 of FIGS. 8 and 9, repeated explanations will not be provided. For example, the first and second gate electrodes G1 and G2 are formed on the first side 100a of the substrate 100, and the first seventh penetrating part P71 and the second seventh penetrating part P72 may penetrate the first and second insulating layers 131 and 132. The seventh connecting part P7 may extend along the second insulating layer 132. For example, each of the first and second gate electrodes G1 and G2 may be the source follower gate electrode SF of FIG. 19.

In the image sensor according to some embodiments, from the viewpoint of a plan view, the seventh connecting part C7 may extend along the pixel separation pattern 120.

In the image sensor according to some embodiments, the first region REG1 may include one first impurity region 101.

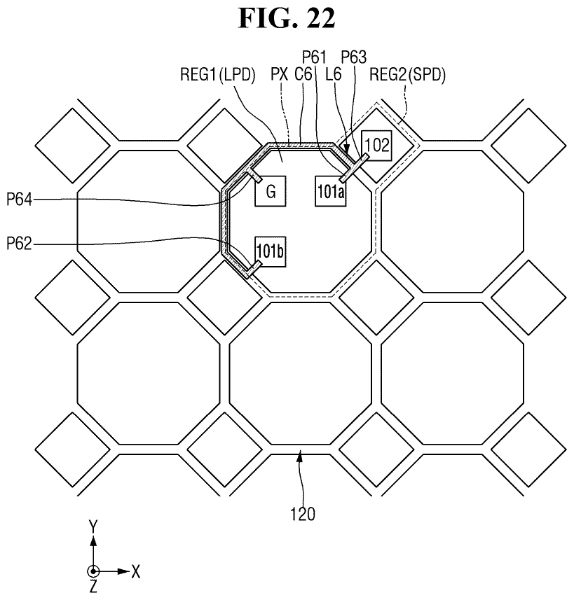

FIG. 22 is an exemplary layout diagram illustrating a pixel array of an image sensor according to some embodiments. For convenience of explanation, points different from those explained using FIGS. 1 to 20 will be mainly explained.

Referring to FIG. 22, in the image sensor according to some embodiments, the gate electrode G and the first impurity regions 101a and 101b in the pixel PX may be connected to each other through wiring of the lower level, which is lower than the first conductive line (ML1 of FIG. 3). The number and placement of gate electrodes G and first impurity regions 101a and 101b connected to each other are merely exemplary and are not limited thereto.

The gate electrode G may be further provided in the first region REG1. The sixth wiring L6 may further connect the gate electrode G and the first impurity regions 101a and 101b.

The sixth wiring L6 may further include a fourth sixth penetrating part P64. The sixth connecting part C6 may connect the first sixth penetrating part P61, the second sixth penetrating part P62, the third sixth penetrating part P63 and the fourth sixth penetrating part P64. The gate electrode G may be the source follower gate electrode SF of FIG. 19. Because the gate electrode G and the fourth sixth penetrating part P64 correspond to the first source follower gate electrode SF1 and the second first penetrating part P12 of FIGS. 2 to 4, repeated explanation will not be provided. The gate electrode G is formed on the first side 100a of the substrate 100, and the fourth sixth penetrating part P64 may penetrate the first and second insulating layers 131 and 132 and may be connected to the gate electrode G. For example, although the gate electrode G and the first and second impurity regions 101a, 101b, and 102 may be each of the source follower gate electrode SF and the third floating diffusion region FD3 of FIG. 19, the embodiment is not limited thereto.

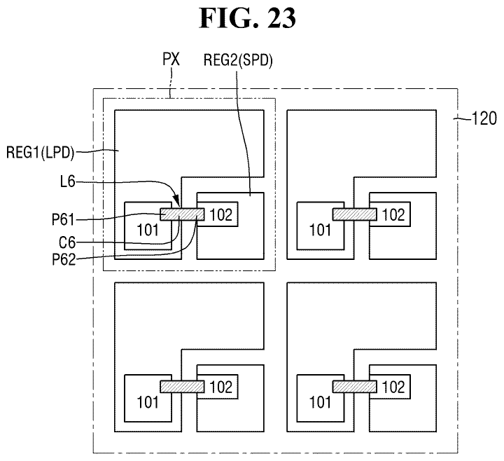

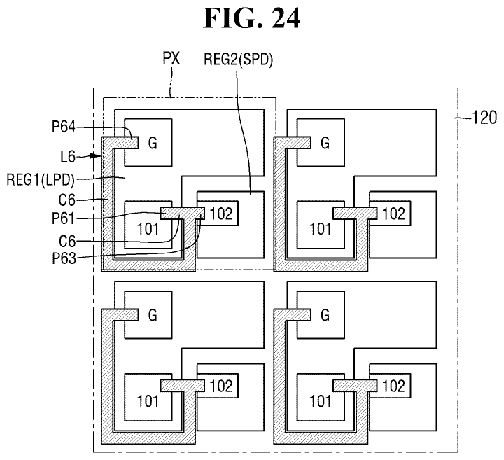

FIGS. 23 and 24 are exemplary layout diagrams illustrating a pixel array of an image sensor according to some embodiments. For convenience of explanation, the explanation will focus on the points that are different from those explained using FIGS. 1 to 22.

Referring to FIGS. 23 and 24, in the image sensor according to some embodiments, from the viewpoint of a plan view, a first region REG1 and a second region REG2 may each have a square shape. The second region REG2 may be provided in an outer portion inside the first region REG1. The pixel PX made up of the first region REG1 and the second region REG2 may also have a rectangular shape. The first region REG1 may have a rectangular shape with only the second region REG2 excluded. The second region REG2 may be provided at a vertex portion of the first region REG1, but the placement of the second region REG2 inside the pixel PX is not limited thereto.

In the image sensor according to some embodiments, the first region REG1 may include one first impurity region 101.

Referring to FIG. 23, the sixth wiring L6 may connect the first impurity region 101 of the first region REG1 and the second impurity region 102 of the second region REG2.

Referring to FIG. 24, the sixth wiring L6 may connect the first impurity region 101 of the first region REG1, the second impurity region 102 of the second region REG2, and the gate electrode G of the first region REG1.

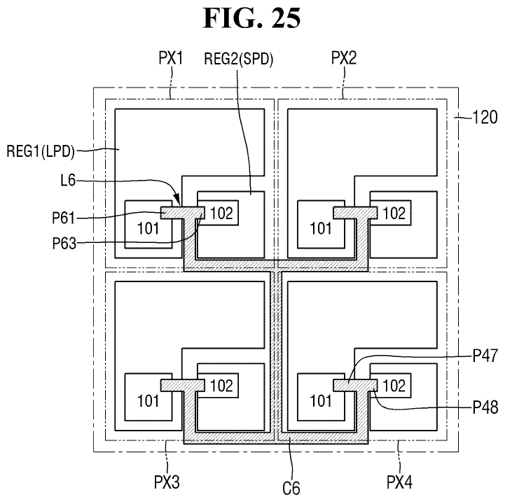

FIGS. 25 to 27 are exemplary layout diagrams illustrating a pixel array of an image sensor according to some embodiments. For convenience of explanation, the explanation will focus on the points that are different from those explained using FIGS. 1 to 23.

Referring to FIGS. 25 to 27, each of the first to fourth pixels PX1, PX2, PX3, and PX4 may correspond to the pixel PX explained using FIG. 23. The first pixel PX1 and the second pixel PX2 may be adjacent to each other in the first direction X, and the third pixel PX3 and the fourth pixel PX4 may be adjacent to each other in the first direction X. The third pixel PX3 and the first pixel PX1 may be adjacent to each other in the second direction Y, and the fourth pixel PX4 and the second pixel PX2 may be adjacent to each other in the second direction Y. The third pixel PX3 and the second pixel PX2 may be adjacent to each other in a diagonal direction between the first direction X and the second direction Y. The first to fourth pixels PX1, PX2, PX3, and PX4 may be arranged in two rows and two columns.

Referring to FIG. 25, in the image sensor according to some embodiments, the sixth wiring L6 may connect the first and second impurity regions 101 and 102 of each of the first to fourth pixels PX1, PX2, PX3, and PX4 to each other. For example, the first and second impurity regions 101 and 102 may be the third floating diffusion region FD3 of FIG. 19.

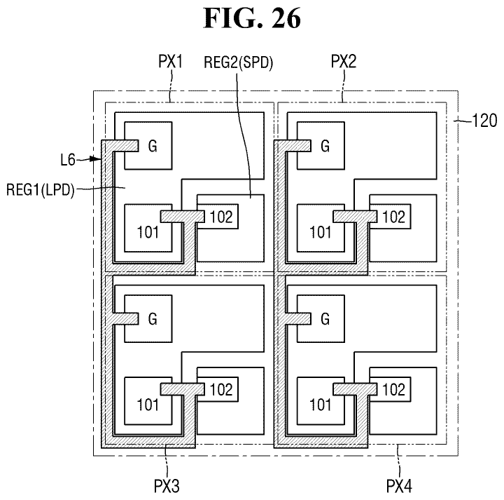

Referring to FIG. 26, in the image sensor according to some embodiments, each of the first to fourth pixels PX1, PX2, PX3, and PX4 may further include a gate electrode G. The sixth wiring L6 may connect the first and second impurity regions 101 and 102 of each of the first and third pixels PX1 and PX3 and the gate electrode G to each other. The sixth wiring L6 may connect the first and second impurity regions 101 and 102 of each of the second and fourth pixels PX2 and PX4 and the gate electrode G to each other.

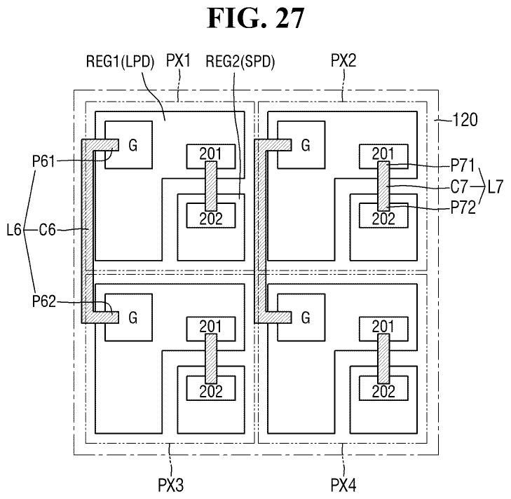

Referring to FIG. 27, in the image sensor according to some embodiments, each of the first to fourth pixels PX1, PX2, PX3, and PX4 may include first and second impurity regions 201 and 202. The seventh wiring L7 may connect the first and second impurity regions 201 and 202 of each of the first to fourth pixels PX1, PX2, PX3, and PX4 to each other. For example, the first and second impurity regions 201 and 202 may be the ground regions of FIG. 19. The placement and number of second impurity regions 202 inside the second region REG2 and the placement and number of first impurity regions 201 inside the first region REGI are merely exemplary and are not limited thereto.

Each of the first to fourth pixels PX1, PX2, PX3, and PX4 may include the gate electrode G. The sixth wiring L6 may connect the gate electrode G of each of the first and third pixels PX1 and PX3 to each other. The sixth wiring L6 may connect the second and fourth pixels PX2 and PX4 to each other.

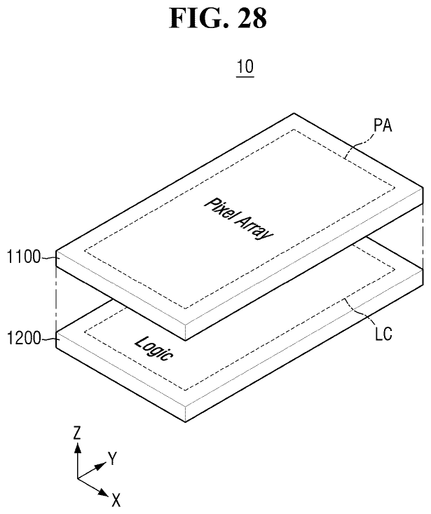

FIG. 28 is a diagram showing a conceptual layout of the image sensor according to some embodiments.

Referring to FIG. 28, the image sensor 10 according to some embodiments may include an upper chip 1100 and a lower chip 1200. The upper chip 1100 and the lower chip 1200 may be stacked. A plurality of pixels may be provided on the upper chip 1100 in a two-dimensional array structure. For example, the plurality of pixels may be arranged in a pixel array (PA). For example, the pixel array may be provided on the upper chip 1100. For example, the pixel array may include any of the pixel arrays illustrated in FIGS. 1 to 27.

The lower chip 1200 may include, but is not limited to, a logic region LC, a memory region, and the like. The lower chip 1200 may be provided below the upper chip 1100 and may be electrically connected to the upper chip 1100. The lower chip 1200 may allow the pixel signal transferred from the upper chip 1100 to be transferred to the logic region LC of the lower chip 1200.

Logic elements may be provided in the logic region LC of the lower chip 1200. The logic elements may include circuits for processing pixel signals from the pixels. For example, the logic elements may include control register blocks, timing generators, ramp signal generators, row drivers, readout circuits, buffer units, and the like.

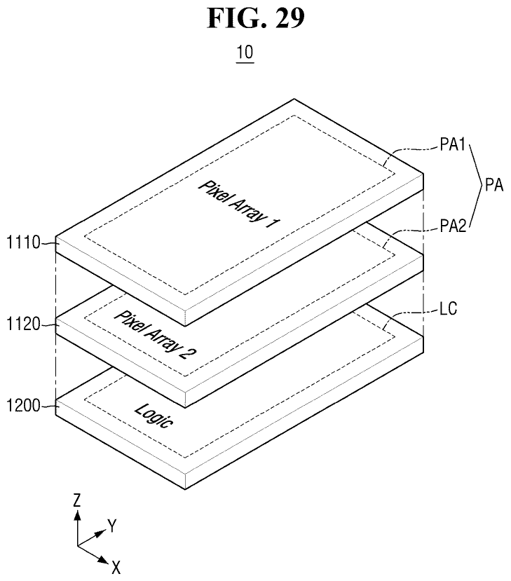

FIG. 29 is a diagram showing a conceptual layout of an image sensor according to some embodiments. For convenience of explanation, points different from those explained using FIGS. 1 to 28 will be mainly explained.

Referring to FIG. 29, the image sensor 10 according to some embodiments may include a first chip 1110, a second chip 1120, and a lower chip 1200.

The pixel array may include a first pixel array PA1 and a second pixel array PA2. The first pixel array PA1 may be provided on the first chip 1110, and the second pixel array PA2 may be provided on the second chip 1120. For example, the pixel arrays PA1 and/or PA2 may include any of the pixel arrays illustrated in FIGS. 1 to 27.

In the image sensor according to some embodiments, the second pixel array PA2 may be provided on either the upper side or the lower side of the second chip 1120. In some other embodiments, the second pixel array PA2 may be provided on the upper side or the lower side of the second chip 1120.

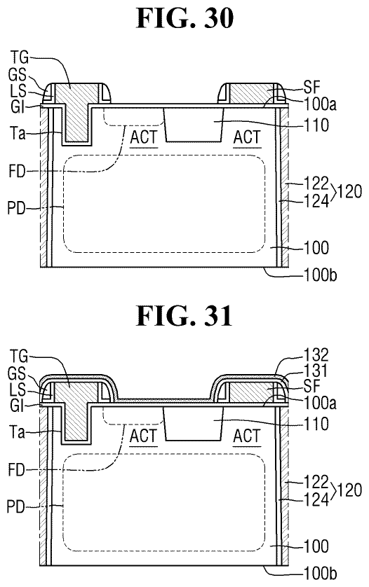

FIGS. 30 to 34 are diagrams illustrating a method of manufacturing an image sensor according to some embodiments. For convenience of explanation, points different from those explained using FIGS. 1 to 29 will be mainly explained.

Referring to FIG. 30, the method may include providing a substrate 100. For example, the method may include providing the substrate 100, which includes a first side 100a and a second side 100b that are opposite to each other. The method may include forming a photodiode PD, a pixel separation pattern 120, an element separation film 110, and an active region ACT in the substrate 100. Moreover, the method may include forming a gate insulating layer GI, a gate spacer GS, a liner spacer LS, a transfer gate electrode TG, and a source follower gate electrode SF on the first side 100a of the substrate 100.

For example, the photodiode PD may be formed by ion-implantation of n-type impurities into the p-type substrate 100. The photodiode PD may be formed inside each pixel arranged inside the substrate 100.

The element separation film 110 may define an active region ACT inside the pixel. The element separation film 110 may extend from the first side 100a of the substrate 100, and may define the active region ACT extending from the first side 100a inside the substrate 100. For example, the element separation film 110 may be formed by a shallow trench isolation (STI) process on the first side 100a of the substrate 100.

The active region ACT may include a floating diffusion region FD. For example, the floating diffusion region FD may be formed by ion-implantation of n-type impurities into the p-type substrate 100.

The method may include forming a first trench Ta extending from the first side 100a of the substrate 100. The gate insulating layer GI may extend along the first side 100a of the substrate 100 and the first trench Ta. The method may include forming a transfer gate electrode TG that fills the first trench Ta on the gate insulating layer GI. The method may include forming a source follower gate electrode SF on the gate insulating layer GI. The method may include forming the liner spacer LS and the gate spacer GS on the side surface of the transfer gate electrode TG and the side surface of the source follower gate electrode SF.

Referring to FIG. 31, the method may include forming a first insulating layer 131 and a second insulating layer 132.

The first insulating layer 131 may be provided on the transfer gate electrode TG, the gate spacer GS, the source follower gate electrode SF, and the gate spacer GS. For example, the first insulating layer 131 may cover the transfer gate electrode TG, the gate spacer GS on the transfer gate electrode TG, the source follower gate electrode SF, and the gate spacer GS on the source follower gate electrode SF. The first insulating layer 131 may be formed conformally along the transfer gate electrode TG, the gate spacer GS, and the source follower gate electrode SF.

The second insulating layer 132 may be conformally formed along the first insulating layer 131.

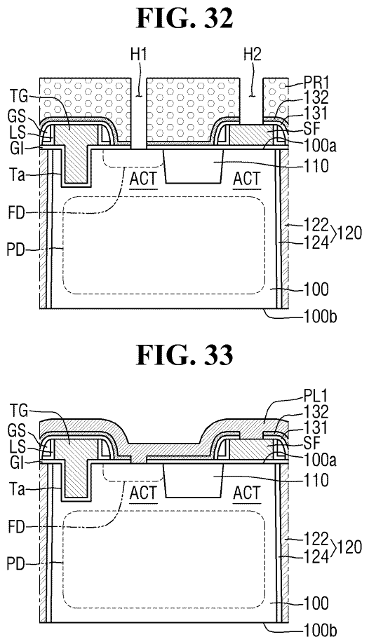

Referring to FIG. 32, the method may include forming a first mask pattern PR1 including a first hole H1 and a second hole H2 on the second insulating layer 132. The first hole H1 is formed on the floating diffusion region FD, and the second hole H2 is formed on the source follower gate electrode SF. The second insulating layer 132 and the gate insulating layer GI exposed by the first hole H1 are removed, and a part of the floating diffusion region FD is exposed. The second insulating layer 132 and the first insulating layer 131 exposed by the second hole H2 are removed, and a part of the source follower gate electrode SF is exposed.

The first mask pattern PR1 may include, for example, a photoresist material.

Referring to FIG. 33, the method may include forming a pre-wiring PL1. The pre-wiring PL1 may be formed on the second insulating layer 132, the exposed floating diffusion region FD, and the source follower gate electrode SF. For example, the pre-wiring PL1 may cover the second insulating layer 132, the exposed floating diffusion region FD, and the source follower gate electrode SF.

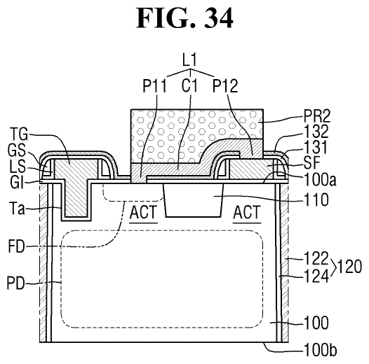

Referring to FIG. 34, the method may include forming a second mask pattern PR2 on the pre-wiring PL1. The pre-wiring PLI is patterned, using the second mask pattern PR2. As a result, the first wiring L1 that connects the floating diffusion region FD and the source follower gate electrode SF is formed.

The second mask pattern PR2 may include, for example, a photoresist material.

Referring to FIG. 18, the method may include forming a third insulating layer 133, a fourth insulating layer 134, and an interlayer insulating film ILD on the second insulating layer 132 and the first wiring L1. For example, the third insulating layer 133, the fourth insulating layer 134, and the interlayer insulating film ILD may be sequentially formed on the second insulating layer 132 and the first wiring L1. A first contact CT12, a first conductive line ML1, and a second conductive line ML2 may be formed.

A surface insulating film 160, a grid pattern 170, a first protective film 176, a color filter 180, and a micro lens 190 may be formed on the second side 100b of the substrate 100.

Although the embodiments of the disclosure have been described above with reference to the accompanying drawings, the disclosure is not limited to the above embodiments, and may be manufactured in various different forms. Those skilled in the art will appreciate that the disclosure may be embodied in other specific forms without changing the technical spirit or essential features of the disclosure. Accordingly, the above-described embodiments should be understood in all respects as illustrative and not restrictive.

What is claimed is:

1. An image sensor comprising:
a substrate comprising a first surface and a second surface opposing to the first surface;
a first pixel comprising a first floating diffusion region (FD) in the substrate;
conductive layers comprising a first conductive line layer disposed on a shortest distance from the first surface of the substrate in a first direction perpendicular to the first surface among conductive line layers in the conductive layers;
a first transistor on the first surface of the substrate; and
a wiring connecting the first FD and the first transistor and disposed between the first surface of the substrate and the first conductive line layer,
wherein the wiring comprises a first portion extending in a second direction perpendicular to the first direction.

2. The image sensor of claim 1, further comprising:
a second pixel comprising a second FD in the substrate;
a third pixel comprising a third FD in the substrate;
a fourth pixel comprising a fourth FD in the substrate; and
a separation pattern in the substrate and defining the first pixel, the second pixel, the third pixel, and the fourth pixel,
wherein the first transistor is shared by the first to fourth FDs, and
wherein the wiring connects the first transistor and the first to fourth FDs.

3. The image sensor of claim 2, wherein the wiring comprises a second portion partially overlapping with each of the first to fourth FDs in the first direction.

4. The image sensor of claim 3, wherein the second portion of the wiring is vertically overlapped with the separation pattern in the first direction.

5. The image sensor of claim 4, wherein the first portion of the wiring has a first width in a third direction perpendicular to the second direction,
wherein the second portion of the wiring has a second width in the third direction, and
wherein the first width of the first portion is less than the second width of the second portion.

6. The image sensor of claim 4, further comprising:
a contact overlapped with the separation pattern in the first direction.

7. The image sensor of claim 6, wherein the separation pattern is in contact with the first surface of the substrate and the second surface of the substrate.

8. The image sensor of claim 6, further comprising:
a first insulating layer on the first portion of the wiring, and
wherein the first insulating layer is disposed between the first portion of the wiring and the first conductive line layer.

9. The image sensor of claim 8, further comprising: a
second insulating layer on the first insulating layer, and
wherein the second insulating layer is disposed between the first insulating layer and the first conductive line layer.

10. The image sensor of claim 9, further comprising:
a third insulating layer disposed between the first surface of the substrate and the first portion of the wiring.

11. The image sensor of claim 9, wherein the contact penetrates the first and second insulating layers.

12. The image sensor of claim 1, wherein a portion of the first transistor extends into the substrate from the first surface of the substrate.

13. The image sensor of claim 1, wherein the first transistor is a first source follower transistor.

14. The image sensor of claim 13, further comprising:
a second source follower transistor, and
wherein the first and second source follower transistors are configured to connect to the first to fourth FDs.

15. The image sensor of claim 14, wherein the wiring is configured to connect the first source follower transistor and the second source follower transistor.

16. An image sensor comprising:
a substrate comprising a first surface and a second surface opposing to the first surface;
a first pixel comprising a first floating diffusion region (FD) in the substrate;
a second pixel comprising a second FD in the substrate;
a third pixel comprising a third FD in the substrate;
a fourth pixel comprising a fourth FD in the substrate;
conductive layers comprising a first conductive line layer disposed on a shortest distance from the first surface of the substrate in a first direction perpendicular to the first surface among conductive line layers in the conductive layers;
a first source follower transistor on the first surface of the substrate; and
a wiring connecting the first to fourth FDs and the first source follower transistor and disposed between the first surface of the substrate and the first conductive line layer,
wherein the wiring comprises a first portion extending in a second direction perpendicular to the first direction.

17. The image sensor of claim 16, wherein the wiring comprises polysilicon.

18. The image sensor of claim 17, further comprising:
a first insulating layer on the first portion of the wiring, and
wherein the first insulating layer is disposed between the first portion of the wiring and the first conductive line layer.

19. The image sensor of claim 18, further comprising:
a second insulating layer disposed between the first surface and the first portion of the wiring.

20. An image sensor comprising:
a substrate comprising a first surface and a second surface opposing to the first surface;
first to fourths pixels sharing a first floating diffusion region (FD) in the substrate;
conductive layers comprising a first conductive line layer disposed on a shortest distance from the first surface in a first direction perpendicular to the first surface among conductive line layers in the conductive layers;
first and second source follower transistors shared by the first to fourth pixels; and
a wiring connecting the first FD and the first and second source follower transistors and disposed between the first surface of the substrate and the first conductive line layer,
wherein the wiring comprises a first portion extending in a second direction perpendicular to the first direction.
